(19) United States
(12) Patent Application Publication
(10) Pub. No.: US 2025/0028249 A1
(43) Pub. Date: Jan. 23, 2025

(54) CHEMICAL SOLUTION

(71) Applicant: FUJIFILM Corporation, Tokyo (JP)

(72) Inventors: Akihiko OHTSU, Shizuoka (JP); Masahiro YOSHIDOME, Shizuoka (JP); Tetsuya KAMIMURA, Shizuoka (JP); Ryo SAITO, Shizuoka (JP)

(73) Assignee: FUJIFILM Corporation, Tokyo (JP)

(21) Appl. No.: 18/893,990

(22) Filed: Sep. 24, 2024

Related U.S. Application Data
(63) Continuation of application No. PCT/JP2023/009118, filed on Mar. 9, 2023.

(30) Foreign Application Priority Data
Mar. 29, 2022 (JP) 2022-052801
Jan. 10, 2023 (JP) 2023-001811

(51) Int. Cl. G03F 7/32; G03F 7/42

(52) U.S. Cl. CPC G03F 7/32; G03F 7/422

(57) ABSTRACT

An object of the present invention is to provide a chemical solution that, in the case of being used in a step of bringing a contact-target member and the chemical solution into contact with each other, is less likely to cause a predetermined defect in the contact-target member. A chemical solution according to the present invention includes an organic solvent and a metal-containing particle including a metal element selected from the group consisting of Fe, Ni, and Zn, wherein an I value determined by a method X is 0.010 to 10.000,
method X: the chemical solution is applied onto a substrate to prepare a subject; a surface of the subject is analyzed by being scanned with laser using laser-ablation-inductively coupled plasma-mass spectrometry, to obtain charts for the metal elements in which an abscissa axis indicates laser scanning time and an ordinate axis indicates ion detection intensity; the ion detection intensity of the charts is accumulated for the scanning time to determine accumulated ion detection intensities of the metal elements; the accumulated ion detection intensities of the metal elements are added up to determine a total accumulated ion detection intensity; and the total accumulated ion detection intensity is divided by a laser scanning area to obtain an I value in units of counts/mm².

### CROSS-REFERENCE TO RELATED APPLICATIONS

This application is a Continuation of PCT International Application No. PCT/JP2023/009118 filed on Mar. 9, 2023, which claims priority under 35 U.S.C. § 119(a) to Japanese Patent Application No. 2022-052801 filed on Mar. 29, 2022 and Japanese Patent Application No. 2023-001811 filed on Jan. 10, 2023. The above applications are hereby expressly incorporated by reference, in their entirety, into the present application.

### BACKGROUND OF THE INVENTION

### 1. Field of the Invention

The present invention relates to a chemical solution.

### 2. Description of the Related Art

During fabrication of semiconductor devices by a circuit formation step including photolithography, chemical solutions including water and/or an organic solvent are used as pre-wet solutions, resist solutions (resist compositions), developers, rinse solutions, stripping solutions, chemical mechanical polishing (CMP: Chemical Mechanical Polishing) slurries, post-CMP washing solutions, and the like or diluted solutions thereof.

In recent years, as the photolithography technology progresses, the dimensions of patterns have been reduced. In order to reduce the dimensions of patterns, the technique of using exposure light sources having shorter wavelengths is employed; exposure light sources that are, instead of ultraviolet rays, KrF excimer laser, ArF excimer laser, and the like having been used, EUV (extreme ultraviolet rays) and the like having shorter wavelengths are used to attempt to form patterns.

Such pattern formation using EUV and the like is being developed with the target resist pattern width of 10 to 15 nm; the above-described chemical solutions used in this process and having higher defect suppression performance are in demand.

The chemical solutions may include, as impurities, metal impurities including metal elements; and the metal impurities can be removed from the chemical solutions by a method of filtering.

JP2016-155121A discloses a method of using a polyimide and/or polyamide-imide porous film having open cells to purify a liquid (chemical solution). JP2016-155121A discloses that use of the method achieved removal of iron (Fe) and zinc (Zn) from the chemical solution.

### SUMMARY OF THE INVENTION

The inventors of the present invention produced a chemical solution with reference to the method of JP2016-155121A, and used it in a step of bringing a contact-target member and the produced chemical solution into contact with each other; and they have found that the chemical solution tends to cause defects in the contact-target member and does not reach the level that has recently been in demand.

When such a chemical solution is used in various applications such as a developer, a rinse solution, a resist washing solution, and a pipe washing solution, the chemical solution desirably does not cause problems in the applications. For example, in the case of using the chemical solution as a developer or a rinse solution, pattern collapse of the formed resist pattern is desirably suppressed. In the case of using the chemical solution as a pre-wet solution, coating unevenness of the resist on a pre-wet substrate is desirably suppressed. In the case of using the chemical solution as a resist washing solution, generation of resist scum is desirably suppressed. In the case of using it as a pipe washing solution, generation of particle defects on the surface of a substrate to which a composition is supplied through the washed pipe is desirably suppressed.

Accordingly, an object of the present invention is to provide a chemical solution that, in the case of being used in a step of bringing a contact-target member and the chemical solution into contact with each other, is less likely to cause defects in the contact-target member and is used as at least one of a developer, a rinse solution, a pre-wet solution, a resist washing solution, or a pipe washing solution; in the case of being used as a developer or a rinse solution, provides suppression of pattern collapse; in the case of being used as a pre-wet solution, provides suppression of coating unevenness of resist; in the case of being used as a resist washing solution, provides suppression of generation of resist scum; or in the case of being used as a pipe washing solution, provides suppression of generation of particle defects on the surface of a substrate to which a composition is supplied through the washed pipe.

The inventors of the present invention performed thorough studies on how to achieve the object and, as a result, have accomplished the present invention. Specifically, they have found that the following features achieve the above-described object.

[1] A chemical solution including:
an organic solvent; and
a metal-containing particle including a metal element selected from the group consisting of Fe, Ni, and Zn,
wherein an I value determined by a method X is 0.010 to 10.000,
method X: the chemical solution is applied onto a substrate to prepare a subject; a surface of the subject is analyzed by being scanned with laser using laser-ablation-inductively coupled plasma-mass spectrometry, to obtain charts for the metal elements in which an abscissa axis indicates laser scanning time and an ordinate axis indicates ion detection intensity; the ion detection intensity of the charts is accumulated for the scanning time to determine accumulated ion detection intensities of the metal elements; the accumulated ion detection intensities of the metal elements are added up to determine a total accumulated ion detection intensity; and the total accumulated ion detection intensity is divided by a laser scanning area to obtain an I value in units of counts/mm².

[2] The chemical solution according to [1], wherein the chemical solution is one selected from the group consisting of a developer, a rinse solution, a pre-wet solution, a resist washing solution, and a pipe washing solution.

[3] The chemical solution according to [1] or [2], wherein the organic solvent includes butyl acetate, 4-methyl-2-pentanol, cyclohexanone, propylene glycol monomethyl ether acetate, or isopropanol.

[4] The chemical solution according to any one of [1] to [3], wherein the chemical solution is a developer,
the organic solvent is selected from the group consisting of butyl acetate and 4-methyl-2-pentanol, or
the organic solvent is a mixture of propylene glycol monomethyl ether acetate and a liquid organic acid.

[5] The chemical solution according to any one of [1] to [3], wherein the chemical solution is a rinse solution, and
the organic solvent is selected from the group consisting of butyl acetate, 4-methyl-2-pentanol, and isopropanol.

[6] The chemical solution according to any one of [1] to [3], wherein the chemical solution is a pre-wet solution, and
the organic solvent is selected from the group consisting of cyclohexanone, propylene glycol monomethyl ether acetate, and isopropanol.

[7] The chemical solution according to any one of [1] to [3], wherein the chemical solution is a resist washing solution, and
the organic solvent is propylene glycol monomethyl ether acetate.

[8] The chemical solution according to any one of [1] to [3], wherein the chemical solution is a pipe washing solution, and
the organic solvent is selected from the group consisting of butyl acetate, 4-methyl-2-pentanol, cyclohexanone, isopropanol, and propylene glycol monomethyl ether acetate.

The present invention can provide a chemical solution that, in the case of being used in a step of bringing a contact-target member and the chemical solution into contact with each other, is less likely to cause defects in the contact-target member and is used as at least one of a developer, a rinse solution, a pre-wet solution, a resist washing solution, or a pipe washing solution; in the case of being used as a developer or a rinse solution, provides suppression of pattern collapse; in the case of being used as a pre-wet solution, provides suppression of coating unevenness of resist; in the case of being used as a resist washing solution, provides suppression of generation of resist scum; or in the case of being used as a pipe washing solution, provides suppression of generation of particle defects on the surface of a substrate to which a composition is supplied through the washed pipe.

### BRIEF DESCRIPTION OF THE DRAWINGS

FIG. 1 is a schematic sectional view illustrating an example of a method of performing laser-ablation-inductively coupled plasma-mass spectrometry in a method X.

### DESCRIPTION OF THE PREFERRED EMBODIMENTS

Hereinafter, the present invention will be described in detail.

Features may be described below on the basis of representative embodiments according to the present invention; however, the present invention is not limited to such embodiments.

Hereinafter, meanings of descriptions in this Specification will be described.

In this Specification, numerical ranges described as “a value ‘to’ another value” mean ranges including the value and the other value as the lower limit value and the upper limit value.

In this Specification, Fe, Ni, and Zn represent symbols of elements and respectively represent iron, nickel, and zinc.

In this Specification, “radiation” means, for example, far-ultraviolet rays, extreme ultraviolet rays (EUV; Extreme ultraviolet), X-rays, or an electron beam. In the present invention, “light” means an actinic ray or a radiation. In the present invention, “exposure” includes, unless otherwise specified, not only exposure using, for example, far-ultraviolet rays, X-rays, or EUV, but also patterning using a corpuscular beam such as an electron beam or an ion beam.

### Chemical Solution

A chemical solution according to the present invention is a chemical solution including an organic solvent and a metal-containing particle including a metal element selected from the group consisting of Fe, Ni, and Zn, wherein an I value determined by a method X described later in detail is 0.010 to 10.000.

Hereinafter, the organic solvent and the metal-containing particle will be described and subsequently the I value and the method X will be described in detail.

Note that, hereafter, in the case of use in a step of bringing a contact-target member and the chemical solution into contact with each other, the result in which defects are less likely to be generated in the contact-target member is also referred to as “defects are less likely to be generated”.

### Organic Solvent

A chemical solution according to the present invention includes an organic solvent.

In this Specification, the organic solvent means a liquid organic compound included in a content of more than 10000 mass ppm per component relative to the total mass of the above-described chemical solution. Thus, in this Specification, a liquid organic compound included in a content of more than 10000 mass ppm relative to the total mass of the above-described chemical solution corresponds to the organic solvent.

In this Specification, liquid means being liquid at 25° C. and at atmospheric pressure.

A chemical solution according to the present invention preferably contains an organic solvent as a main component.

In the chemical solution, the organic solvent is a main component, which means that the content of the organic solvent in the chemical solution relative to the total mass of the chemical solution is 98.0 mass % or more, preferably more than 99.0 mass %, more preferably 99.90 mass % or more, and still more preferably more than 99.95 mass %. The upper limit is less than 100 mass %.

Such organic solvents may be used alone or in combination of two or more thereof. In the case of using two or more organic solvents, the total content thereof is preferably in such a range.

The type of the organic solvent is not particularly limited, and publicly known organic solvents can be used. Examples of the organic solvent include alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds that may have a ring (preferably having 4 to 10 carbon atoms), alkylene carbonates, alkyl alkoxyacetates, alkyl pyruvates, dialkylsulfoxides, cyclic sulfones, dialkyl ethers, monohydric alcohols, glycols, alkyl acetates, and N-alkylpyrrolidones.

The organic solvent is preferably, for example, one or more selected from the group consisting of propylene glycol monomethyl ether acetate (PGMEA), propylene glycol monomethyl ether (PGME), cyclohexanone (CHN), ethyl lactate (EL), propylene carbonate (PC), isopropanol (IPA), 4-methyl-2-pentanol (MIBC), butyl acetate (nBA), propylene glycol monoethyl ether, propylene glycol monopropyl ether, methyl methoxypropionate, cyclopentanone, 7-butyrolactone, diisoamyl ether, isoamyl acetate, dimethyl sulfoxide, N-methylpyrrolidone, diethylene glycol, ethylene glycol, dipropylene glycol, propylene glycol, ethylene carbonate, sulfolane, cycloheptanone, 2-heptanone, and liquid organic acids (for example, formic acid, acetic acid, propionic acid, butyric acid, and lactic acid (racemic body)).

Examples of the case of using two or more organic solvents include combined use of PGMEA and PGME, combined use of PGMEA and PC, and combined use of PGMEA and one or more selected from the group consisting of formic acid, acetic acid, propionic acid, butyric acid, and lactic acid (racemic body).

Note that, the type and content of the organic solvent in the chemical solution can be measured using a gas-chromatograph-mass spectrometer.

### Metal-Containing Particle

A chemical solution according to the present invention includes a metal-containing particle including a metal element selected from the group consisting of Fe, Ni, and Zn.

From the metal-containing particle, the ions derived from the metal-containing particle are detected by laser-ablation-inductively coupled plasma-mass spectrometry and an I value, which will be described later in detail, is determined.

A preferred embodiment of a method for producing the chemical solution will be described later; the chemical solution can be produced by purifying a purification-target substance including the organic solvent and impurities. The metal-containing particle may be intentionally added in a step for producing the chemical solution, may be included in the purification-target substance, or may move from a production apparatus or the like for the chemical solution in the process of producing the chemical solution (what is called, contamination).

The metal-containing particle, which includes a metal element selected from the group consisting of Fe, Ni, and Zn, is not limited in terms of the form thereof. For example, it may be a simple substance of the metal element, may be a compound including the metal element (hereafter, also referred to as “metal compound”), or may be a composite or the like of the foregoing. The chemical solution may include a plurality of metal-containing particle species.

The metal-containing particle may include, in a single metal-containing particle, two or more of the metal elements.

An element other than the above-described metal elements included in the metal compound is not particularly limited and examples thereof include other metal elements and non-metal elements. Examples of the other metal elements include aluminum (Al), titanium (Ti), chromium (Cr), and lead (Pb). Examples of the non-metal elements include hydrogen (H), carbon (C), nitrogen (N), oxygen (O), sulfur (S), and phosphorus (P); of these, preferred is oxygen. The form in which the metal compound includes an oxygen atom is not particularly limited, but is more preferably an oxide of the metal element.

The composite is not particularly limited, but examples thereof include, what is called, a core-shell particle having a simple substance of a metal element and a metal compound covering at least a portion of the simple substance of the metal element, a solid solution particle including a metal element and another element, an aggregate particle of a simple substance of a metal element and a metal compound, an aggregate particle of different metal compounds, and a metal compound whose composition continuously or intermittently varies from the surface to the center of the particle.

### I Value

A chemical solution according to the present invention has an I value determined by a method X below of 0.010 to 10.000. The I value is defined as representing the amount of the predetermined metal elements included in the chemical solution. The smaller the I value, the smaller the amount of the predetermined metal elements.

Method X: the chemical solution is applied onto a substrate to prepare a subject; the surface of the subject is analyzed by being scanned with laser using laser-ablation-inductively coupled plasma-mass spectrometry to obtain charts for the metal elements (Fe, Ni, and Zn) in which the abscissa axis indicates laser scanning time and the ordinate axis indicates ion detection intensity; the ion detection intensity in the charts is accumulated for the scanning time to determine accumulated ion detection intensities of the metal elements; the accumulated ion detection intensities of the metal elements are added up to determine a total accumulated ion detection intensity; and the total accumulated ion detection intensity is divided by a laser scanning area to determine an I value in units of counts/mm².

The I value is preferably 0.010 to 5.000, and more preferably 0.010 to 2.500.

Hereinafter, the method X will be described.

### Subject

In the method X, first, the chemical solution is applied onto a substrate to prepare a subject.

The substrate preferably has high cleanliness of the substrate surface. The substrate may be a semiconductor substrate; more specifically, a silicon wafer can be used. The size of the substrate is not particularly limited, and is appropriately determined in accordance with, for example, the specification of the application apparatus for applying the chemical solution to the substrate, the specification of the apparatus for performing the analysis, and the amount of the chemical solution measured.

The application method of the chemical solution is not particularly limited and may be, for example, spin-coating. The apparatus for applying the chemical solution may be, for example, a coater-developer.

### LA-ICP-MS

In the method X, the subject is analyzed by laser-ablation-inductively coupled plasma-mass spectrometry (LASER-Ablation-Inductively Coupled Plasma-Mass Spectrometry, hereafter also referred to as “LA-ICP-MS”).

LA-ICP-MS is a method in which a sample surface is irradiated with laser to melt and vaporize the sample surface, to generate a gas or fine particles derived from the sample surface, or a mixture of the foregoing (hereafter, also referred to as “vaporized substance”); the vaporized substance derived from the sample surface is introduced into an inductively coupled plasma-mass spectrometry (ICP-MS) section and quantitative analysis of elements included in the vaporized substance derived from the sample surface is performed.

LA-ICP-MS enables analysis of even a very small amount of an element component present in the surface of the subject.

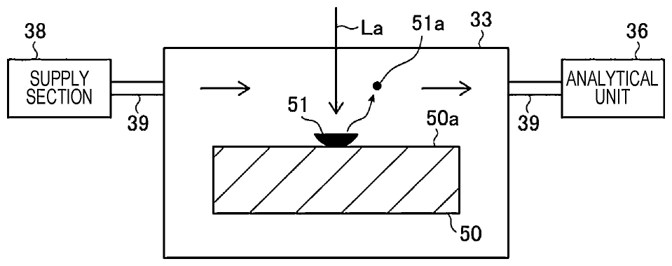

The specific method of performing LA-ICP-MS is not particularly limited, but may be, for example, an analytical method illustrated in FIG. 1.

FIG. 1 is a schematic sectional view illustrating an example of the method for performing LA-ICP-MS.

In the method illustrated in FIG. 1, to a container section 33, a carrier gas supply section 38 and an analytical unit 36 are connected. The container section 33 and the supply section 38 are connected together via a pipe 39, and the container section 33 and the analytical unit 36 are connected together via a pipe 39.

The container section 33 can store a subject 50; the analysis is performed while the entirety of the subject 50 is stored within the container section 33 and a carrier gas is supplied into the container section 33 from the carrier gas supply section 38.

Subsequently, as illustrated in FIG. 1, a surface 50a of the subject 50 is irradiated with a laser beam La. Note that FIG. 1 schematically illustrates a state in which a metal-containing particle 51 included in the chemical solution is irradiated with the laser beam La. Upon irradiation of the metal-containing particle 51 with the laser beam La, ablation occurs to generate a vaporized substance derived from the metal-containing particle 51, namely, an analytical sample 51a. The generated analytical sample 51a is moved by the carrier gas to the analytical unit 36. The analytical sample 51a derived from the metal-containing particle 51 is analyzed by ICP-MS in the analytical unit 36.

The irradiation with the laser beam La is performed while its position is changed, in other words, the laser beam La is scanned, and analysis by ICP-MS is performed each time, to thereby obtain charts for the metal elements in which the abscissa axis indicates laser scanning time and the ordinate axis indicates ion detection intensity.

The irradiation with the laser beam is preferably pulse irradiation; in the present invention, the irradiation with the laser beam is performed using a laser beam and conditions described later.

The analytical unit 36 will be described.

The analytical unit 36 uses the above-described ICP-MS and is configured to perform mass spectroscopy for the analytical sample 51a having been described with reference to FIG. 1.

In the analytical unit 36, high-temperature plasma kept by high-frequency electromagnetic induction is used to ionize the measurement target, and the ions are detected with a mass spectroscopic apparatus (mass spectrometer), to thereby measure the mass of the ions and the number of the ions (ion detection intensity).

The mass spectrometer can be a publicly known mass spectrometer. The mass spectrometer may be, for example, a time-of-flight (Time Of Flight) mass spectrometer, a quadrupole (Quadrupole) mass spectrometer, or a magnetic-field mass spectrometer, and preferred is the quadrupole mass spectrometer (QMS).

The analytical unit 36 provides, for example, signals of detected element ions (not shown) and charts in which the abscissa axis indicates laser scanning time and the ordinate axis indicates ion detection intensity (not shown). The concentration of such a detected element corresponds to the intensity of the ion detection signals.

### Detection Intensity Charts

The above-described method is performed to analyze the surface of the subject by scanning laser using LA-ICP-MS, to obtain charts for metal elements (hereafter, also referred to as “detection intensity charts”) in which the abscissa axis indicates laser scanning time and the ordinate axis indicates ion detection intensity (units: counts). Specifically, obtained are an Fe detection intensity chart C_{Fe}, a Ni detection intensity chart C_{Ni}, and a Zn detection intensity chart C_{Zn}.

Note that, in this Specification, the detection intensity chart C_{Fe}, the detection intensity chart C_{Ni}, and the detection intensity chart C_{Zn} are obtained by performing measurement under conditions below and processing below.

Note that, hereinafter, first, a method for analyzing a single subject by LA-ICP-MS simultaneously for Fe, Ni, and Zn to obtain detection intensity charts (C_{Fe}, C_{Ni}, and C_{Zn}) will be described in detail.

### Preparation of Subject

In the preparation of the subject, a silicon wafer (manufactured by Shin-Etsu Handotai Co., Ltd., 12 inches) is used and the amount of the chemical solution applied is 1 mL. The chemical solution is applied by spin-coating and the spin rate during spin-coating is 500 revolutions/min.

### LA-ICP-MS Measurement Conditions

The laser scanning region (analytical region) is the whole surface of the silicon wafer.

The laser for irradiation is a pulse laser emitted from titanium-doped sapphire serving as the medium and having a wavelength of 260 nm, and having a pulse width of 290 femtoseconds and a fluence of 1 J/cm²; the lasing frequency of the pulse laser is 10 kHz and the irradiation diameter of the pulse laser is 10 km.

The laser is scanned linearly at 100 mm/s; the laser is scanned from one end to the other end of the silicon wafer; subsequently the laser is scanned in the reverse direction (from the other end to the one end) from a position displaced by 10 μm in a direction orthogonal to the scanning direction; this is repeated to scan the whole surface of the wafer.

The carrier gas employed is argon gas or helium gas and the carrier gas is supplied at 10 mL/min.

To the plasma torch, argon gas is supplied and a high-frequency current at 40.68 MHz and at 1.3 kW is applied to generate plasma. The nebulizer employed is of the coaxial type; the flow rate of the nebulizer is set to 0.94 L/min; the amount of argon gas supplied for cooling is set to 13 L/min.

For the mass spectrometric section, a quadrupole mass spectrometer is used. In the ion detector, the detection mode is set to the selected ion detection (SIM) mode; m/z of the ions detected are 56 (Fe), 58 (Ni), and 64 (Zn). The detection time (cycle time) for detecting once each of the ion species at m/z is set to 3 milliseconds. In other words, switch scanning of sequentially and selectively detecting some ion species of different m/z (measurement-target ion species) is performed. In the switch scanning, the ion amounts of some ion species having specified m/z can be repeatedly measured in a short time; a single period in which the plurality of measurement-target ion species serving as the measurement targets are each detected once corresponds to the detection time. Note that, in the detection time, the time for detecting a single measurement-target ion species is referred to as counting time.

For the measurement conditions, reference can also be made to Yamashita et al., BUNSEKI RIGAKU Vol. 68, No 1, pp. 1-7 (2019), and Hirata et al., J. Mass. Spectrom. Soc. Jpn Vol. 67, No. 5, pp. 160-166 (2019).

Note that, for example, the ion detection intensity (units: counts) of the ions at m/z=56 during the detection time can be calculated by multiplying the ion detection count rate (units: counts/s) during the counting time for detecting the ions at m/z=56, by the detection time; a value for the ion detection intensity corresponding to the ion detection intensity at m/z=56 in the case of detecting only the ions at m/z=56 during the detection time can be estimated.

### Signal Processing Method

Hereinafter, a signal processing method for obtaining the detection intensity chart C_{Fe}, the detection intensity chart C_{Ni}, and the detection intensity chart C_{Zn} will be described.

First, a silicon wafer without application of the chemical solution is measured by the above-described method, to obtain, for each of m/z, a background chart C_{B}n in which the abscissa axis indicates laser scanning time and the ordinate axis indicates ion detection intensity. Note that n represents the value of m/z; for example, the background chart for m/z=56 is referred to as a background chart C_{B56}; the background chart C_{Bn} is the generic name for the background charts provided by measurement for each of m/z.

In the background chart C_{Bn}, the average value of the ion detection intensity is defined as a background average value I_{Bnave}; in the background chart C_{Bn}, the standard deviation of the ion detection intensity is defined as a standard deviation σ_{Bn}. Note that, for example, in the background chart C_{B56}, the average value of the ion detection intensity is referred to as a background average value I_{B56ave} and the standard deviation of the ion detection intensity is referred to as a standard deviation σ_{B56}.

Note that, for example, in the background chart C_{B56}, the ion detection intensity (units: counts) during the detection time is a value calculated by multiplying the ion detection count rate (units: counts/s) during the counting time for detecting the ions at m/z=56, by the detection time.

Subsequently, another wafer of the same type as the wafer used for obtaining the background chart C_{Bn} is subjected to, by the above-described procedures, application of the chemical solution to obtain a subject; the above-described measurement is performed, to obtain mass spectra in which m/z in each detection time are the above-described values. Thus, the ion detection intensity (units: counts) for each m/z is plotted along the ordinate axis and the scanning time is plotted along the abscissa axis to thereby also obtain a pre-processing detection intensity chart C_{m/z=n}. Note that n represents the value of m/z; for example, a pre-processing detection intensity chart at m/z=56 is referred to as a pre-processing detection intensity chart C_{m/z=56}; the pre-processing detection intensity chart C_{m/z=n} is a generic name for the pre-processing detection intensity chart provided by measurement for each of m/z.

Note that, for example, in the pre-processing detection intensity chart C_{m/z=56}, the ion detection intensity (units: counts) during the detection time is a value calculated by multiplying the ion detection count rate (units: counts/s) during the counting time for detecting the ions at m/z=56, by the detection time.

The detection intensity chart C_{Fe}, the detection intensity chart C_{Ni}, and the detection intensity chart C_{Zn} are individually obtained by subjecting the pre-processing detection intensity chart C_{m/z=n} to signal processing below. The method for obtaining the detection intensity chart C_{Fe} will be described as a representative.

For iron (Fe), there are stable isotopes that are ⁵⁴Fe, ⁵⁶Fe, ⁵⁷Fe, and ⁵⁸Fe; ⁵⁶Fe has the highest natural abundance. In order to obtain the detection intensity chart C_{Fe}, the ions at m/z corresponding to ⁵⁶Fe are used as the detection target. Thus, the pre-processing detection intensity chart C_{m/z=56} of the ions at m/z corresponding to ⁵⁶Fe is obtained and subjected to signal processing and analysis, to obtain the detection intensity chart C_{Fe}.

The pre-processing detection intensity chart C_{m/z=56} corresponding to ⁵⁶Fe can include background and noise. For this reason, first, a corrected chart C_{m/z=56} provided by subtracting the background average value I_{B56ave} from the pre-processing detection intensity chart C_{m/z=56} is obtained.

Furthermore, in the post-subtraction corrected chart C_{m/z=56}, signals having a detection intensity that is 6 or more times the standard deviation σ_{B56} are regarded as the signals due to the ions at m/z=56.

When signals during detection times in the corrected chart C_{m/z=56} are not regarded as the signals due to the ions at m/z=56, processing in which the ion detection intensity during the detection times is regarded as 0 is performed. A chart obtained by subjecting the corrected chart C_{m/z=56} to the processing for each of the detection times is defined as the detection intensity chart C_{Fe}.

Note that the detection intensity chart C_{Fe} corresponds to a chart in which, in the case of detecting ions at m/z=56 alone, the ion detection intensity at m/z=56 is estimated.

The same signal processing as above is performed to obtain the detection intensity chart C_{Ni} and the detection intensity chart C_{Zn}.

Note that, for nickel (Ni), there are stable isotopes that are ⁵⁸Ni, ⁶⁰Ni, ⁶¹Ni, ⁶²Ni, and ⁶⁴Ni and ⁵⁸Ni has the highest natural abundance; thus, in order to obtain the detection intensity chart C_{Ni}, the ions at m/z corresponding to ⁵⁸Ni are used as the detection target.

For zinc (Zn), there are stable isotopes that are ⁶⁴Zn, ⁶⁶Zn, ⁶⁷Zn, ⁶⁸Zn, and ⁷⁰Zn, and ⁶⁴Zn has the highest natural abundance; thus, in order to obtain the detection intensity chart C_{Zn}, the ions at m/z corresponding to ⁶⁴Zn are used as the detection target.

Calculation of I value

The method for calculating the I value from the detection intensity charts (C_{Fe}, C_{Ni}, and C_{Zn}) for the metal elements will be described.

For the detection intensity charts (C_{Fe}, C_{Ni}, and C_{Zn}), the ion detection intensity (units: counts) is accumulated for the scanning time to obtain accumulated ion detection intensities of the metal elements (units: counts). Specifically, Fe accumulated ion detection intensity I_{Fe}, Ni accumulated ion detection intensity I_{Ni}, and Zn accumulated ion detection intensity I_{Zn} are obtained. The term accumulated means that, in each of the charts, the ion detection intensity is entirely added up over the scanning time.

Subsequently, accumulated ion detection intensities of the metal elements are added up to provide a total accumulated ion detection intensity (the total value of the accumulated ion detection intensity I_{Fe}, the accumulated ion detection intensity I_{Ni}, and the accumulated ion detection intensity I_{Zn}).

The total accumulated ion detection intensity is divided by the laser scanning area to provide the I value. The I value is provided in units of counts/mm².

Note that, in the above-described method, a single subject is subjected to simultaneous analysis of Fe, Ni, and Zn by LA-ICP-MS to obtain the detection intensity charts (C_{Fe}, C_{Ni}, and C_{Zn}); alternatively, the following method of using different subjects may be employed.

Specifically, the same chemical solution may be applied to a plurality of substrates of the same type to prepare a plurality of subjects; one of the subjects may be subjected to analysis of one of the elements by LA-ICP-MS; in this way, the detection intensity charts (C_{Fe}, C_{Ni}, and C_{Zn}) may be obtained. For example, among the plurality of subjects, a subject is analyzed by LA-ICP-MS for the ions at m/z=56 alone and background and noise are removed in accordance with the above-described method, to obtain the detection intensity chart C_{Fe} in which the abscissa axis indicates laser scanning time and the ordinate axis indicates ion detection intensity. Note that, in the case of using the above-described method to obtain the detection intensity chart C_{Fe}, the background chart C_{B56}, the background average value I_{B56ave}, and the standard deviation σ_{B56} employed are obtained by analyzing, for the ions at m/z=56 alone, by LA-ICP-MS, a substrate without application of the chemical solution. Other subjects are analyzed by the same procedures to obtain also the detection intensity chart C_{Ni} and the detection intensity chart C_{Zn}.

### Other Component

A chemical solution according to the present invention may include, in addition to those described above, another component. Examples of the other component include organic compounds other than organic solvents (in particular, organic compounds having a boiling point of 300° C. or more), water, and resins.

The other component may be a solid organic acid. The solid organic acid means an organic acid that is solid at 25° C. and at atmospheric pressure. Examples of the solid organic acid include oxalic acid, malonic acid, succinic acid, fumaric acid, maleic acid, glutaric acid, tartronic acid, malic acid, tartaric acid, glycolic acid, citric acid, and lactic acid (D-lactic acid or L-lactic acid).

The total content of the other component relative to the total mass of the chemical solution is preferably 2 mass % or less, more preferably 1 mass % or less, and still more preferably 0.1 mass % or less. The total content of the other component is, for example, relative to the total mass of the chemical solution, preferably more than 0 mass %.

The total content of the solid organic acid relative to the total mass of the chemical solution is preferably 1 mass % or less, more preferably 0.001 mass % or less, and still more preferably 0.0001 mass % or less.

### Applications of Chemical Solution

Applications of a chemical solution according to the present invention are not particularly limited.

In particular, the application of the chemical solution is preferably use in a method (process) for producing a semiconductor device. In other words, the method for producing a semiconductor device preferably has a step of using a chemical solution according to the present invention.

The chemical solution can be used in any step for producing a semiconductor device. In particular, the chemical solution is preferably used in a step including formation of a resist pattern. In other words, a resist pattern forming method preferably has a step of using a chemical solution according to the present invention.

Specifically, it is preferably used for a method for producing a semiconductor device and a method for washing a semiconductor production apparatus. More specifically, the chemical solution is, for example, preferably used in an application selected from the group consisting of a developer, a rinse solution, a pre-wet solution, a resist washing solution, and a pipe washing solution. Alternatively, the chemical solution may also be used for an edge rinse solution, a back rinse solution, and a thinner for dilution.

The developer is used in order to remove, from an exposed resist film, the exposed region or the unexposed region and is used for forming a resist pattern. The organic solvent included in the developer is preferably butyl acetate (nBA), 4-methyl-2-pentanol (methylisobutylcarbinol, MIBC), propylene glycol monomethyl ether acetate (PGMEA), or a solvent mixture including propylene glycol monomethyl ether acetate (PGMEA) and one or more liquid organic acids selected from the group consisting of formic acid, acetic acid, propionic acid, butyric acid, and lactic acid. Such a developer including a solvent mixture including propylene glycol monomethyl ether acetate (PGMEA) and one or more liquid organic acids selected from the group consisting of formic acid, acetic acid, propionic acid, butyric acid, and lactic acid is preferably used when the resist film is formed of a metal resist.

The rinse solution is mainly used for washing the post-development resist film.

The above-described edge rinse solution refers to a rinse solution that is supplied to the peripheral portion of a semiconductor substrate in order to remove the resist film in the peripheral portion of the semiconductor substrate. The organic solvent included in the rinse solution is preferably butyl acetate (nBA), isopropanol (IPA), or 4-methyl-2-pentanol (MIBC).

The pre-wet solution is supplied onto a semiconductor substrate before formation of a resist film and is used in order to facilitate spreading of the resist solution over the semiconductor substrate and to reduce the amount of resist solution supplied for forming a homogeneous resist film. The organic solvent included in the pre-wet solution is preferably cyclohexanone (CHN), propylene glycol monomethyl ether acetate (PGMEA), or isopropanol (IPA).

The resist washing solution is used for washing a semiconductor substrate on which a resist pattern has been formed (stripping of the resist pattern). The organic solvent included in the resist washing solution is preferably propylene glycol monomethyl ether acetate (PGMEA).

The pipe washing solution is used for, for example, washing of a pipe of a semiconductor production apparatus. The organic solvent included in the pipe washing solution is preferably propylene glycol monomethyl ether acetate (PGMEA), cyclohexanone (CHN), butyl acetate (nBA), isopropanol (IPA), or 4-methyl-2-pentanol (MIBC).

The resist composition used for forming the resist film can be a publicly known resist composition.

Note that the resist composition may be, what is called, a metal resist composition.

The metal resist composition may be a photosensitive composition that can form a coating including a metal oxo-hydroxo network having an organic ligand due to a metal-carbon bond and/or a metal-carboxylate bond.

Examples of the metal resist composition include the compositions described in JP2019-113855A, the contents of which are incorporated herein by reference.

The organic solvents included in the developer, the rinse solution, and the resist washing solution may also be preferably, for example, organic solvents such as acetic acid, butyl acetate, 4-methyl-2-pentanol, propionic acid, butyric acid, butyl butyrate, isobutyl isobutyrate, formic acid, isoamyl formate, isoamyl ether, pentyl propionate, isopentyl propionate, ethylcyclohexane, mesitylene, decane, undecane, 3,7-dimethyl-3-octanol, 2-ethyl-1-hexanol, 1-octanol, 2-octanol, ethyl acetoacetate, dimethyl malonate, methyl pyruvate, dimethyl oxalate, propylene glycol monomethyl ether acetate (PGMEA), propylene glycol monomethyl ether (PGME), methyl ethyl ketone (MEK), 2-pentanol, and isopropanol (IPA). Such an organic solvent may be a mixture of, in an appropriate ratio, two or more organic solvents selected from the group consisting of the above-described organic solvents.

As described above, a chemical solution according to the present invention is a chemical solution including an organic solvent and a metal-containing particle including a metal element selected from the group consisting of Fe, Ni, and Zn, wherein the I value obtained by the above-described method X is 0.010 to 10.000.

In the case of use for the step of bringing a chemical solution according to the present invention and a contact-target member into contact with each other, the mechanism by which defects are less likely to be generated in the contact-target member is not necessarily clarified, but is inferred by the inventors of the present invention as follows. Note that the following mechanism is an inference and cases in which an object of the present invention is achieved by a mechanism other than the following mechanism are also included in the scope of the present invention.

The inventors of the present invention have thoroughly studied on the cause of generation of defects in the case of applying chemical solutions to the step of bringing such a chemical solution and various contact-target members into contact with each other. As a result, they have found that, for the first time, when the I value is 10.000 or less, defects derived from the metal-containing particle (particle defects) are less likely to be generated. In addition, when the I value is 0.010 or more, a certain amount of the metal-containing particle is included, so that charging of the chemical solution is relaxed and problems in the applications in the contact-target members are suppressed by the following mechanism, inferentially.

When such a contact-target member is an exposed resist film or resist pattern, the application of the chemical solution is a developer or a rinse solution. When the I value is 0.010 or more, charging of the chemical solution is relaxed, so that repulsion or attraction due to charging of the chemical solution is less likely to act on the resist pattern, which results in suppression of defects (pattern collapse). Note that the defects (pattern collapse) tend to occur when the resist pattern has small line widths.

Alternatively, when the contact-target member is a semiconductor substrate (such as a silicon wafer), the application of the chemical solution is a pre-wet solution. When the I value is 0.010 or more, charging of the chemical solution is relaxed, so that charging of the surface of the semiconductor substrate in contact with the chemical solution is relaxed, and the resist-film-forming composition to be applied in a later step tends to uniformly spread. As a result, defects (coating unevenness of the resist) are less likely to be generated. Even when the non-contact member has a resist lower layer film on the semiconductor substrate, the same mechanism inferentially provides advantages.

Alternatively, when the contact-target member has a semiconductor substrate (such as a silicon wafer) and one or more selected from the group consisting of a resist film and a resist pattern (hereafter, also referred to as “resist film or the like”), the application of the chemical solution is a resist washing solution. When the I value is 0.010 or more, charging of the chemical solution is relaxed, so that charging of the surface of the semiconductor substrate and the resist film or the like in contact with the chemical solution is relaxed, and the chemical solution tends to spread over the surface of the semiconductor substrate and the surface of the resist film or the like. As a result, the resist washing solution tends to come into contact with the whole surface of the resist film or the like, the resist film or the like is easily stripped, and defects (generation of resist scum) are less likely to be generated.

Alternatively, when the contact-target member is a pipe (such as a pipe of a semiconductor production apparatus), the application of the chemical solution is a pipe washing solution. When the I value is 0.010 or more, charging of the chemical solution is relaxed, so that, upon passing of the chemical solution through the pipe, charging between the wall surface of the pipe and the chemical solution is less likely to occur, and sparks are less likely to be generated. As a result, particle defects in post-pipe washing steps are suppressed.

Thus, in the case of use in the step of bringing a chemical solution according to the present invention and a contact-target member into contact with each other, defects are less likely to be generated in the contact-target member and occurrence of problems in various applications is suppressed, inferentially. Also in other contact-target members and applications, by the same or similar mechanism, defects are less likely to be generated in the contact-target members, inferentially.

Note that large amounts of Fe, Ni, and Zn are often included in organic solvents, compared with other metal elements; even after filtration or the like, particles including such elements tend to remain and are metal-containing particles inferentially governing properties of chemical solutions including an organic solvent.

When the application of the chemical solution is a developer or a rinse solution, the I value is preferably 0.010 to 5.000, and more preferably 0.010 to 1.200.

When the application of the chemical solution is a pre-wet solution, the I value is preferably 0.010 to 5.000, and more preferably 0.030 to 2.200.

When the application of the chemical solution is a resist washing solution, the I value is preferably 0.010 to 5.000, and more preferably 0.020 to 2.400.

When the application of the chemical solution is a pipe washing solution, the I value is preferably 0.010 to 5.000, and more preferably 0.020 to 2.400.

### Method for Producing Chemical Solution

The method for producing the chemical solution is not particularly limited and a publicly known production method can be used. In particular, from the viewpoint of more easily obtaining the chemical solution, preferred is a method for producing a chemical solution having the following steps in this order. Hereinafter, the steps will be described in detail.
(1) Organic-solvent preparation step of preparing organic solvent
(2) Filtration step of passing purification-target substance including organic solvent through filter to obtain chemical solution

### (1) Organic-Solvent Preparation Step of Preparing Organic Solvent

The organic-solvent preparation step is a step of preparing an organic solvent. The method for preparing an organic solvent is not particularly limited and examples thereof include obtaining the organic solvent by purchase or the like and causing a raw material to react to obtain the organic solvent as the reaction product. Note that the organic solvent prepared preferably has a low content of a metal-containing particle including a metal element and/or organic impurities (for example, having an organic solvent content of 99 mass % or more). Commercially available products of such organic solvents are, for example, those referred to as “high-purity grade products”.

Note that the organic solvent prepared may be composed of a single compound or may be an organic solvent mixture that is a mixture composed of two or more.

The method of causing a raw material to react to obtain the organic solvent as the reaction product is not particularly limited and a publicly known method can be used. For example, it may be a method of, in the presence of a catalyst, causing one or a plurality of raw materials to react, to obtain the organic solvent.

More specifically, examples include a method of causing acetic acid and n-butanol to react in the presence of sulfuric acid to obtain butyl acetate; a method of causing ethylene, oxygen, and water to react in the presence of Al(C₂H₅)₃ to obtain 1-hexanol; a method of causing cis-4-methyl-2-pentene to react in the presence of Ipc2BH (Diisopinocampheylborane) to obtain 4-methyl-2-pentanol; a method of causing propylene oxide, methanol, and acetic acid to react in the presence of sulfuric acid to obtain PGMEA (propylene glycol 1-monomethyl ether 2-acetate); a method of causing acetone and hydrogen to react in the presence of copper oxide-zinc oxide-aluminum oxide to obtain IPA (isopropyl alcohol); and a method of causing lactic acid and ethanol to react to obtain ethyl lactate.

### (2) Filtration Step of Passing Purification-Target Substance Including Organic Solvent Through Filter to Obtain Chemical Solution

The filtration step is a step of passing the purification-target substance including an organic solvent through a filter to obtain the chemical solution. In this Specification, the purification-target substance means, for example, the reaction product obtained in the organic-solvent preparation step, the purification product obtained in a distillation step described later, and the organic solvent obtained by purchase or the like in the organic-solvent preparation step.

From the viewpoint of easily producing a chemical solution according to the present invention, the specific procedures of the filtration step are preferably passing the purification-target substance including an organic solvent through a first metal-ion adsorption filter, a first particle removal filter having a pore size of 10 nm or less, a second metal-ion adsorption filter, a second particle removal filter having a pore size of 10 nm or less, a third metal-ion adsorption filter, and a third particle removal filter having a pore size of 10 nm or less in this order, to perform filtration. Note that the first particle removal filter, the second particle removal filter, and the third particle removal filter are individually formed of different materials that are individually selected from the group consisting of a fluororesin, a polyamide-based resin, and a polyolefin-based resin.

In the filtration step, the filtration process from the first metal-ion adsorption filter to the third particle removal filter may be circulated. The number of circulations is, for example, 2 to 8 times and more preferably 2 to 5 times.

The above-described method can effectively reduce the I value to adjust the I value to a range of the present invention. The detailed mechanism by which the method can adjust the I value to a range of the present invention is not necessarily clarified, but is inferred as follows.

Fe, Ni, and Zn have different chemical properties and a particle including Fe, a particle including Ni, and a particle including Zn behave differently in the organic solvent, inferentially. For example, for particles including different elements, the particles often have different surface potentials in the organic solvent. Such particles having different surface potentials are different in interactivity with other objects such as particle removal filters in the organic solvent. Thus, use of a single particle removal filter can result in low removal rates of particles including specified elements. For this reason, the above-described method of using the first particle removal filter, the second particle removal filter, and the third particle removal filter that are individually formed of different materials is performed to thereby effectively remove all the particle species that are the particle including Fe, the particle including Ni, and the particle including Zn, which results in effective reduction in the I value inferentially.

Fe, Ni, and Zn can also be individually present as ions in the organic solvent inferentially and are in an equilibrium state between the particle form and the ion form inferentially. In this case, even in the case of having removed the particles using particle removal filters, the particle removal filters cannot remove the ions and, without completion of removal of the ions, particles can be generated from the remaining ions. Conversely, even in the case of having removed the ions alone using ion removal filters, ions can be generated from the remaining particles. Accordingly, when the organic solvent is passed through an ion removal filter and a particle removal filter alternately, both of such a particle and such an ion can be removed before one of them is generated from the other, which inferentially results in effective reduction in the I value.

On the other hand, particle removal filters tend not to capture particles less than the filter pore sizes and the filter pore sizes vary, so that it is difficult to remove particles completely. Note that it is difficult to remove particles using ion removal filters. For this reason, the number of circulations can be set appropriately to thereby adjust the I value to a range of the present invention.

Hereinafter, the filtration step will be described in detail.

### Metallic-Ion Adsorption Filters

In the filtration step, the first metal-ion adsorption filter to the third metal-ion adsorption filter are used. Use of the filters can reduce the number of ions in the purification-target substance.

The first metal-ion adsorption filter to the third metal-ion adsorption filter may be filters of the same type or may be filters of different types.

The metal-ion adsorption filters are not particularly limited and can be publicly known metal-ion adsorption filters.

In particular, preferred metal-ion adsorption filters are ion-exchangeable filters. The metal ion serving as the adsorption target is preferably at least one metal ion species selected from the group consisting of Fe, Ni, and Zn, and more preferably all these metal ions of Fe, Ni, and Zn.

The metal-ion adsorption filters preferably have an acid group in the surfaces from the viewpoint of having improved adsorption performance for metal ions. Examples of the acid group include a sulfo group and a carboxy group.

Examples of the base material (material) forming the metal-ion adsorption filters include cellulose, diatomaceous earth, nylon, polyethylene, polypropylene, polystyrene, and fluororesin.

Alternatively, the metal-ion adsorption filters may be formed of a material including polyimide and/or polyamide-imide. Examples of the metal-ion adsorption filters include the polyimide and/or polyamide-imide porous films described in JP2016-155121A.

The polyimide and/or polyamide-imide porous films may include at least one selected from the group consisting of a carboxy group, a salt-type carboxy group, and a —NH— bond. When the metal-ion adsorption filters are formed of fluororesin, polyimide, and/or polyamide-imide, it has higher solvent resistance.

The method of passing the purification-target substance through the metal-ion adsorption filters (the first metal-ion adsorption filter to the third metal-ion adsorption filter) is not particularly limited and may be a method in which a metal-ion adsorption filter unit including the metal-ion adsorption filters and a filter housing is disposed at an intermediate position of the transfer pipe line for transferring the purification-target substance, and the purification-target substance under application of pressure or no pressure is passed through the metal-ion adsorption filter unit.

### Particle Removal Filters

In the filtration step, the first particle removal filter to the third particle removal filter are used. Use of the filters can reduce particle components including the predetermined metal elements in the purification-target substance.

The first particle removal filter to the third particle removal filter are filters of different types. In other words, the first particle removal filter to the third particle removal filter are individually formed of different materials that are individually selected from the group consisting of fluororesin, polyamide-based resin, and polyolefin-based resin.

Note that, for example, a case in which the first particle removal filter is formed of polypropylene and the second particle removal filter is formed of polyethylene corresponds to an example in which both are formed of different materials.

The first particle removal filter to the third particle removal filter have a pore size (particle retention rating) of 10 nm or less, preferably 8 nm or less, and more preferably 5 nm or less. The lower limit is not particularly limited, but is often 1 nm or more.

The pore size (particle retention rating) used herein means the minimum size of particles that the filter can remove. For example, when a filter has a particle retention rating of 10 nm, particles having diameters of 10 nm or more can be removed.

The materials of the first particle removal filter to the third particle removal filter are selected from the group consisting of fluororesin, polyamide-based resin, and polyolefin-based resin, and examples thereof include 6-nylon, 6,6-nylon, polyethylene, polypropylene, and polytetrafluoroethylene (PTFE).

The polyamide-based resin may have at least one selected from the group consisting of a carboxy group, a salt-type carboxy group, and a —NH— bond.

The method of passing the purification-target substance through the particle removal filters (the first particle removal filter to the third particle removal filter) is not particularly limited, and may be a method in which a particle removal filter unit including the particle removal filters and a filter housing is disposed at an intermediate position of the transfer pipe line for transferring the purification-target substance, and the purification-target substance is passed through the particle removal filter unit under application of pressure or no pressure.

In the filtration step, during passing of the purification-target substance through the filters, the temperature of the purification-target substance is not particularly limited, but is, in general, preferably 0 to 30° C., and more preferably 0 to 15° C.

The filtration pressure affects filtration accuracy and hence pulsation in the pressure during filtration is preferably minimized.

In the method for producing the chemical solution, the filtration rate is not particularly limited, but is preferably 1.0 L/min/m² or more, more preferably 0.75 L/min/m² or more, and still more preferably 0.6 L/min/m² or more.

Filters have allowable differential pressures under which the filter performance (filters are not damaged) is ensured; when such a value is large, the filtration pressure can be increased to thereby increase the filtration rate. In other words, the upper limit of the filtration rate ordinarily depends on the allowable differential pressure of filters, but is ordinarily preferably 10.0 L/min/m² or less.

In the method for producing the chemical solution, the filtration pressure is preferably 0.001 to 1.0 MPa, more preferably 0.003 to 0.5 MPa, and still more preferably 0.005 to 0.3 MPa. In particular, in the case of using a filter having a small pore size, the filtration pressure can be increased to thereby efficiently reduce the amount of particulate foreign matter or impurities dissolving in the purification-target substance. In the case of using a filter having a pore size of less than 20 nm, the filtration pressure is particularly preferably 0.005 to 0.3 MPa.

As long as the filtration step includes a process of passing the purification-target substance from the first metal-ion adsorption filter to the third particle removal filter, another filter may be further disposed and the purification-target substance may be passed therethrough.

### (3) Optional Steps

The method for producing the chemical solution may include, in addition to the filtration step, as optional steps, an organic-impurity removal step, a distillation step, a moisture adjustment step, a discharging step, and the like. Hereinafter, the optional steps will be described in detail.

### Organic-Impurity Removal Step

The filtration step may further have an organic-impurity removal step. The organic-impurity removal step is preferably a step of passing the purification-target substance through an organic-impurity adsorption filter. The method of passing the purification-target substance through an organic-impurity adsorption filter is not particularly limited, and may be a method in which a filter unit including an organic-impurity adsorption filter and a filter housing is disposed at an intermediate position of the transfer pipe line for transferring the purification-target substance, and the organic solvent is passed through the filter unit under application of pressure or no pressure.

The organic-impurity adsorption filter is not particularly limited and may be a publicly known organic-impurity adsorption filter.

In particular, the organic-impurity adsorption filter preferably has, in the surface, an organic skeleton that can interact with an organic impurity (stated another way, the surface is modified with an organic skeleton that can interact with an organic impurity) from the viewpoint of having improved adsorption performance for the organic impurity. The organic skeleton that can interact with an organic impurity may be, for example, a chemical structure that can react with an organic impurity to capture the organic impurity with the organic-impurity adsorption filter. More specifically, in the case of including, as the organic impurity, an n-long-chain alkyl alcohol (structural isomer in the case of using, as the organic solvent, a 1-long-chain alkyl alcohol), the organic skeleton may be an alkyl group. Alternatively, in the case of including, as the organic impurity, dibutylhydroxytoluene (BHT), the organic skeleton may be a phenyl group.

Examples of the base material (material) forming the organic-impurity adsorption filter include activated-carbon-supported cellulose, diatomaceous earth, nylon, polyethylene, polypropylene, polystyrene, and fluororesin.

Alternatively, the organic-impurity adsorption filter may be the filters in which activated carbon is fixed on nonwoven fabric in JP2002-273123A and JP2013-150979A.

For the organic-impurity adsorption filter, other than the above-described chemical adsorption (adsorption using an organic-impurity removal filter having, in the surface, an organic skeleton that can interact with an organic impurity), a physical adsorption method can be applied.

For example, in the case of including, as the organic impurity, BHT, BHT has a structure larger than 10 Å (=1 nm). Thus, an organic-impurity adsorption filter having a pore size of 1 nm is used, so that BHT cannot pass through the pores of the filter. In other words, BHT is physically captured by the filter and hence removed from the purification-target substance. Thus, for the removal of the organic impurity, not only chemical interaction, but also the physical removal method can be applied. Note that, in this case, a filter having a pore size of 3 nm or more is used as a “particle removal filter” and a filter having a pore size of less than 3 nm is used as an “organic-impurity adsorption filter”.

In this Specification, 1 Å (angstrom) is 0.1 nm.

### Distillation Step

The method for producing the chemical solution may include a distillation step. The distillation step means a step of distilling the organic solvent or the reaction product, to obtain a purification product. The method of distillation is not particularly limited and a publicly known method can be used.

When the method for producing the chemical solution has the distillation step, the order thereof with respect to the above-described steps is not particularly limited; however, from the viewpoint of more easily obtaining the chemical solution, the method preferably has the distillation step after the organic-solvent preparation step and before the filtration step.

### Moisture Adjustment Step

The method for producing the chemical solution may include a moisture adjustment step. The moisture adjustment step is a step of adjusting the content of water included in the purification-target substance. The method of adjusting the water content is not particularly limited, but examples thereof include a method of adding water to the purification-target substance and a method of removing water in the purification-target substance.

The method of removing water is not particularly limited and a publicly known dehydration method can be used.

For the method of removing water, examples include a dehydration membrane, a water adsorbent insoluble in organic solvents, an aeration-purge apparatus using dry inert gas, and a heating or vacuum-heating apparatus.

In the case of using a dehydration membrane, membrane dehydration by pervaporation (PV) or vapor permeation (VP) is performed. The dehydration membrane is constituted as, for example, a water-permeable membrane module. The dehydration membrane may be a membrane formed of a material of polymer-based such as polyimide-based, cellulose-based, or polyvinyl alcohol-based or a material of inorganic-based such as zeolite.

The water adsorbent is used by being added to the purification-target substance. Examples of the water adsorbent include zeolite, diphosphorus pentaoxide, silica gel, calcium chloride, sodium sulfate, magnesium sulfate, zinc chloride anhydride, fuming sulfuric acid, and soda lime.

Note that, in the case of using, in the dehydration process, zeolite (in particular, for example, MOLECULAR SIEVE (trade name) manufactured by Union Showa K.K.), olefins can also be removed.

### Discharging Step

The method for producing the chemical solution may include a discharging step. The discharging step is a step of discharging the purification-target substance to thereby reduce the charging potential of the purification-target substance.

The discharging method is not particularly limited and a publicly known discharging method can be used. The discharging method may be, for example, a method of bringing the purification-target substance into contact with a conductive material.

The contact time for bringing the purification-target substance into contact with the conductive material is preferably 0.001 to 60 seconds, more preferably 0.001 to 1 second, and still more preferably 0.01 to 0.1 seconds. Examples of the conductive material include stainless steel, gold, platinum, diamond, and glassy carbon.

The method of bringing the purification-target substance into contact with the conductive material may be, for example, a method in which a mesh formed of the conductive material and grounded is disposed within a pipe line and the purification-target substance is passed through the pipe line.

The method has the discharging step preferably before at least one step selected from the group consisting of the organic-solvent preparation step, the distillation step, and the filtration step.

Note that the above-described steps are preferably performed in a sealed state and in an inert gas atmosphere in which ingress of water into the purification-target substance is less likely to occur.

The steps are preferably performed in an inert gas atmosphere having a dew point temperature of −70° C. or less in order to suppress ingress of moisture as much as possible. This is because, in the inert gas atmosphere at −70° C. or less, the gas phase has a moisture concentration of 2 mass ppm or less and hence the probability of ingress of moisture into the purification-target substance lowers.

Note that the method for producing the chemical solution may include, in addition to the above-described steps, for example, the adsorption purification treatment step for metal components using silicon carbide described in WO2012/043496A.

In the method for producing the chemical solution, in the apparatuses related to the production, portions that come into contact with the chemical solution are preferably washed before production of the chemical solution according to the present invention. The liquid used in the washing is not particularly limited, but is preferably the chemical solution itself or a diluted solution of the chemical solution, for example. Alternatively, an organic solvent that substantially do not include particles including metal atoms, metal ion components, or organic impurities or that has sufficiently lowered contents of particles including metal atoms, metal ion components, and organic impurities can be used. The washing may be performed a plurality of times; two or more organic solvents may be used or may be used in mixture. Circulation washing may be performed. Whether or not the apparatuses related to the production are sufficiently washed can be determined by measuring the contents of particles including metal atoms, metal ion components, and organic impurities included in the liquid having been used for the washing.

### Container

The chemical solution may be temporarily stored in a container until use. The container for storing the chemical solution is not particularly limited and a publicly known container can be used.

The container for storing the chemical solution is preferably a container applied to semiconductor applications, having high cleanliness within the container, and tending not to leach impurities.

Non-limiting specific examples of the container usable include “CLEANBOTTLE” series manufactured by AICELLO CHEMICAL CO., LTD. and “PUREBOTTLE” manufactured by KODAMA PLASTICS Co., Ltd.

This container has a solution contact portion preferably formed of a non-metal material.

Examples of the non-metal material include the above-described materials exemplified for the non-metal material used for the solution contact portion of the distillation column.

In particular, among those described above, in the case of using a container having a solution contact portion formed of a fluororesin, the occurrence of a problem of leaching of oligomers of ethylene or propylene can be suppressed, compared with the case of using a container having a solution contact portion formed of a polyethylene resin, a polypropylene resin, or a polyethylene-polypropylene resin.

Specific examples of the container having a solution contact portion formed of a fluororesin include FluoroPurePFA composite drums manufactured by Entegris Inc. Also usable are the containers described in page 4 and the like of JP1991-502677 Å (JP-H3-502677A), page 3 and the like of WO2004/016526A, and pages 9, 16, and the like of WO99/46309A. Note that, in the case of using a solution contact portion formed of a non-metal material, leaching from the non-metal material into the chemical solution is preferably suppressed.

Alternatively, in the container, the solution contact portion that comes into contact with the chemical solution is preferably formed of a metal material including Cr atoms and Fe atoms, and the metal material is preferably at least one selected from the group consisting of stainless steel and electropolished stainless steel.

The form of the stainless steel is the same as in the above-described material of the solution contact portion of the distillation column. The same applies to the electropolished stainless steel.

The inside of the container is preferably washed before the solution is stored. The liquid used for the washing is preferably the chemical solution itself or a diluted solution of the chemical solution. The chemical solution after its production may be bottled into a container such as a gallon bottle or a quart bottle, transported, and stored. The gallon bottle may be formed of a glass material or another material.

In order to prevent alterations of components in the solution during storage, the container may be purged with an inert gas (such as nitrogen or argon) having a purity of 99.99995 vol % or more. In particular, preferred is a gas having a low moisture content. The transportation and storage may be performed at the ordinary temperature or in the controlled temperature range of −20° C. to 30° C. in order to prevent deterioration.

The production of the chemical solution, opening and/or washing of the container, handling of the solution including storage of the solution, processing and analysis, and measurements are all preferably performed in a clean room. The clean room preferably satisfies the 14644-1 clean room standard. It preferably satisfies any one of ISO (the International Organization for Standardization) Class 1, ISO Class 2, ISO Class 3, and ISO Class 4, more preferably satisfies ISO Class 1 or ISO Class 2, and still more preferably satisfies ISO Class 1.

### Chemical-Solution Storage Container

A chemical solution according to the present invention may be provided as the form of a chemical-solution storage container including a container and the chemical solution stored in the container.

Within the container, the solution contact portion in contact with the chemical solution is also preferably formed of a metal material including Cr atoms and Fe atoms, and the metal material is also preferably at least one selected from the group consisting of stainless steel and electropolished stainless steel.

Note that the form of the container is the same as the above-described preferred examples of the container that can store the chemical solution.

### Method for Producing Chemical-Solution Storage Container

The method for producing the chemical-solution storage container is not particularly limited, and a publicly known production method can be used. In particular, from the viewpoint of more easily obtaining the chemical-solution storage container, preferred is a method for producing a chemical solution having the following steps in this order. Hereinafter, the steps will be described in detail.
(1) Organic-solvent preparation step of preparing organic solvent
(2) Filtration step of passing purification-target substance including organic solvent through filter to obtain chemical solution
(3) Storage step of storing chemical solution into container to obtain chemical-solution storage container

### (1) Organic-Solvent Preparation Step of Preparing Organic Solvent

The method for producing the chemical-solution storage container preferably has an organic-solvent preparation step. The form of the organic-solvent preparation step is the same as the above-described form of the method for producing a chemical solution.

### (2) Filtration Step of Passing Purification-Target Substance Including Organic Solvent Through Filter to Obtain Chemical Solution

The method for producing the chemical-solution storage container preferably has a filtration step. The form of the filtration step is the same as the above-described form of the method for producing a chemical solution.

(3) Storage Step of Storing Chemical Solution into Container to Obtain Chemical-Solution Storage Container

The method for producing the chemical-solution storage container preferably has a storage step. The method for storing the chemical solution into a container is not particularly limited and a publicly known storage method can be used.

Note that the form of the container is the same as the above-described form of the container included in the chemical-solution storage container.

In the storage step, the temperature of the chemical solution during storage of the chemical solution into the container is not particularly limited, but is preferably, in general, 0 to 30° C., and more preferably 0 to 10° C.

For the method for storing the chemical solution into a container, from the viewpoint of more easily obtaining the chemical-solution storage container and, in the chemical-solution storage step, being less likely to undergo entry of unintended impurities into the chemical solution, the following storage apparatus is more preferably used to store the chemical solution into the container.

### Storage Apparatus

A form of the storage apparatus that can be used in the chemical-solution storage step may be a storage apparatus having a chemical-solution storage section and the chemical-solution storage section may have a solution contact portion formed of at least one selected from the group consisting of a non-metal material and an electropolished metal material.

Note that the forms of the non-metal material and the electropolished metal material are the same as those of the above-described materials of the solution contact portion of the distillation apparatus.

### Storage Apparatus (Other Form)

Another form of the storage apparatus that can be used in the chemical-solution storage step may be a storage apparatus including a chemical-solution storage section and a chemical-solution supply pipe line connected to the chemical-solution storage section and configured to supply the chemical solution to a chemical-solution supply section, wherein the chemical-solution supply pipe line has a solution contact portion formed of at least one selected from the group consisting of a non-metal material and an electropolished metal material.

Note that the forms of the non-metal material and the electropolished metal material are the same as those of the above-described materials of the solution contact portion of the distillation apparatus.

The storage apparatus according to this embodiment includes the chemical-solution supply pipe line connected to the chemical-solution storage section. This chemical-solution supply pipe line is connected to a pipe line configured to transfer the purification-target substance used in the filtration step. Thus, the chemical solution obtained in the filtration step is transferred to the chemical-solution storage section in the closed system, to thereby further suppress entry of impurities into the chemical solution.

### Preferred Embodiment of Method for Producing Chemical-Solution Storage Container

The method for producing the chemical-solution storage container more preferably has the following steps.
(1) Organic-solvent preparation step of preparing organic solvent
(2) Filtration step of passing purification-target substance including organic solvent through filter to obtain chemical solution
(3) Storage step of storing chemical solution into container to obtain chemical-solution storage container

The forms of the organic-solvent preparation step and the filtration step are the same as the above-described forms in the method for producing a chemical solution. The form of the storage step is the same as the above-described form in the method for producing a chemical-solution storage container.

The method for producing a chemical-solution storage container enables easier production of the chemical-solution storage container.

### Method for Producing Resist Pattern

The chemical solution can be used for a method for producing a resist pattern.

In general, the method for producing a resist pattern has the following steps and the chemical solution is preferably used in any one of the following steps of the production method.
Step 1: a step of using a resist composition to form a resist film on a semiconductor substrate
Step 2: a step of subjecting the resist film to pattern exposure
Step 3: a step of using a developer to develop the resist film having been subjected to pattern exposure, to obtain a resist pattern

Note that the method may have, before the step 1, a step 4 of applying a pre-wet solution onto the substrate.

The method may have, after the step 3, a step 5 of using a rinse solution to rinse the resist pattern.

The method may further have, after the step 3 or after the step 5, a step 6 of using a resist washing solution to strip the resist pattern.

The chemical solution can be used as, for example, an organic solvent included in the pre-wet solution, the developer, the rinse solution, the resist washing solution, and the like.

In the step 1, the resist composition employed can be a publicly known resist composition.

For the method of applying the resist composition, publicly known application method and application apparatus (such as a coater-developer) can be used.

The semiconductor substrate employed can be a publicly known semiconductor substrate (such as a silicon wafer).

In the step 2, the method for exposing the resist film employed can be a publicly known method. Examples of the light source used for the exposure include far-ultraviolet rays, X-rays, and EUV and corpuscular beams such as an electron beam and an ion beam.

In the step 3, the development method employed can be a publicly known method.

The chemical solution can also be applied to a method for producing a semiconductor device having a step of using the chemical solution. Examples of the step of using the chemical solution include steps in the method for producing a resist pattern, the washing of a semiconductor substrate using the chemical solution, and the washing of a semiconductor production apparatus using the chemical solution (for example, washing of a pipe).

### EXAMPLES

Hereinafter, the present invention will be described further in detail with reference to Examples.

Materials, amounts of usage, ratios, contents of treatments, procedures of treatments, and the like in Examples below can be appropriately changed without departing from the spirit and scope of the present invention. Thus, the scope of the present invention should not be construed as being limited to Examples below.

In the preparation of the chemical solutions of Examples and Comparative Examples, handling of the containers, preparation, charging, storage, and analysis-measurement of the chemical solutions were all performed in a clean room satisfying ISO Class 2 or 1.

### Production of Chemical Solutions

Purification-target substances including organic solvents were purified under conditions in Tables later, to obtain chemical solutions used in Examples and Comparative Examples.

Note that, for each of the chemical solutions, the purification-target substance was passed through the filters (first filter to sixth filter) in Tables and passed through the filters the number of times described in the “Number of circulations” column. Note that, for the chemical solutions in which filter columns are blank, the corresponding filters were not used.

Note that, in Tables, for example, “PGMEA80/Acetic acid 20” means that a solvent mixture of 80 mass % of PGMEA and 20 mass % of acetic acid was used as the purification-target substance.

Note that the purification-target substances in Tables were acquired in different lots. Thus, components other than the organic solvents originally included in the purification-target substances may be different.

In Tables, for “Lactic acid”, lactic acid of racemic body was used.

Hereinafter, abbreviations in Tables will be described.

### Organic Solvents

nBA: butyl acetate
MIBC: 4-methyl-2-pentanol
CHN: cyclohexanone
PGMEA: propylene glycol monomethyl ether acetate
IPA: isopropanol

### Filters

IEX: ion-exchange filter (“IonKlee”, manufactured by Pall Corporation)
Nylon: nylon filter (“Asymmetric”, manufactured by Pall Corporation)
PP: polypropylene filter (“NanoSHIELD”, manufactured by 3M Company)
PTFE: polytetrafluoroethylene filter (“XpressKLEEN”, manufactured by Pall Corporation)
UPE: ultrahigh molecular weight polyethylene filter (“Microgard”, manufactured by Entegris, Inc.)
Note that, for filters having pores, their pore sizes are described in Tables.

### Measurement by LA-ICP-MS

Subjects using the chemical solutions were prepared and analyzed by LA-ICP-MS in accordance with the above-described method X, to determine I values (counts/mm²) for the chemical solutions. Note that the above-described method X is a method in which different subjects are used and each subject is analyzed by LA-ICP-MS for a single element to obtain detection intensity charts (C_{Fe}, C_{Ni}, and C_{Zn}). The results will be described in Tables later.

Note that the measurement by the above-described method revealed detection of Fe, Ni, and Zn in each of the chemical solutions.

### Evaluation of Developer and Rinse Solution

A method described below was performed to evaluate generation of defects in the cases of using the chemical solutions (Examples 1 to 20 and Comparative Examples 1 to 20) as developers or rinse solutions. Note that, for the test, a coater-developer “RF^{3S}” manufactured by SOKUDO Co., Ltd. was used.

First, AL412 (manufactured by Brewer Science, Inc.) was applied onto a silicon wafer and baked at 200° C. for 60 seconds, to form a resist underlayer film having a film thickness of 20 nm. This was coated with a pre-wet solution (solvent mixture of PGMEA and propylene carbonate in 3:1), and further coated with a resist composition 1 described later. After the coating with the resist composition 1, baking (PB: Prebake) was performed at 100° C. for 60 seconds to form a resist film having a film thickness of 30 nm.

This resist film was exposed using an EUV exposure apparatus (manufactured by ASML; NXE3350, NA: 0.33, Dipole 90°, outer sigma: 0.87, inner sigma: 0.35) through a reflective-type mask having a pitch of 20 nm and a pattern width of 10 nm. Subsequently, heating (PEB: Post Exposure Bake) was performed at 85° C. for 60 seconds.

Subsequently, in Examples 1 to 10 and Comparative Examples 1 to 10, the chemical solution of each of Examples and Comparative Examples was used as the developer to perform development for 30 seconds. Subsequently, the wafer was rotated at a rotation rate of 2000 rpm for 40 seconds, to thereby form a line-and-space pattern having a pitch of 20 nm and a pattern line width of 10 nm.

Note that, in Examples 11 to 20 and Comparative Examples 11 to 20, after PEB was performed, the chemical solution of Example 1 was used as the developer to perform development for 30 seconds, and the chemical solutions of Examples and Comparative Examples were used to perform rinsing for 20 seconds. Subsequently, patterns were formed as in Examples 1 to 10 and Comparative Examples 1 to 10.

In the patterns formed by the above-described procedures, the number of occurrences of pattern collapse was measured with UVision8 manufactured by Applied Materials, Inc. and a fully automatic defect review classification apparatus “SEMVision G7E” of Applied Materials, Inc.

The particle defects were measured using a combination of a wafer inspection apparatus “SP-7” manufactured by KLA-Tencor Corporation and a fully automatic defect review classification apparatus “SEMVision G7E” manufactured by Applied Materials, Inc.

Note that the particle defects refer to particulate defects remaining in formed patterns and having particle sizes of 5 nm or more. The particle defects were measured and detected by the method described in Paragraphs 0015 to 0067 of JP2009-188333A. Specifically, before formation of a resist pattern, a CVD (chemical vapor deposition) process was performed to form a SiOₓ thin film layer on a wafer in advance; after formation of the resist pattern, oxygen plasma was used to strip the resist; an etching apparatus (Tactras-Vigas, manufactured by Tokyo Electron Ltd.) was used to etch particles and SiOₓ, and particles equal to or larger than the detection lower limit of the wafer inspection apparatus were counted.

Hereinafter, the resist resin composition 1 used for the evaluation of the developer and the rinse solution will be described. The resist resin composition 1 was obtained by mixing together the following components.

### Resist Composition 1

The resist composition 1 was obtained by mixing together components in accordance with the following formula.
Resin (A-1): 0.77 g
Acid generator (B-1): 0.03 g
Basic compound (E-3): 0.03 g
PGMEA: 67.5 g
EL: 75 g

### Resin (A) and the Like

### Synthesis Example 1: Synthesis of Resin (A-1)

A 2 L flask was charged with 600 g of cyclohexanone and purged with nitrogen at a flow rate of 100 mL/min for 1 hour. Subsequently, 4.60 g (0.02 mol) of polymerization initiator V-601 (manufactured by Wako Pure Chemical Industries, Ltd.) was added and heating was performed until the internal temperature reached 80° C. Subsequently, the following monomers and 4.60 g (0.02 mol) of polymerization initiator V-601 (manufactured by Wako Pure Chemical Industries, Ltd.) were dissolved in 200 g of cyclohexanone, to prepare a monomer solution. The monomer solution was added dropwise, over 6 hours, to the flask heated at 80° C. After completion of the dropwise addition, the reaction was further caused at 80° C. for 2 hours.
4-Acetoxystyrene: 48.66 g (0.3 mol)
1-Ethylcyclopentyl methacrylate: 109.4 g (0.6 mol)
Monomer 1: 22.2 g (0.1 mol)

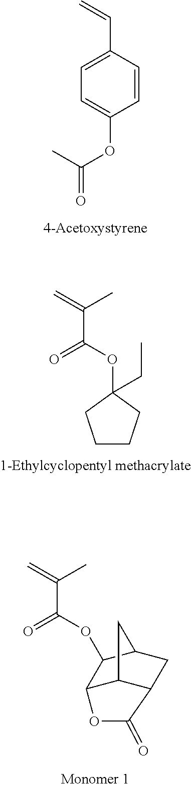

The reaction solution was cooled to room temperature and added dropwise to 3L of hexane to precipitate a polymer. The solid obtained by filtration was dissolved in 500 mL of acetone, and added dropwise again to 3L of hexane; the solid obtained by filtration was dried under a reduced pressure, to obtain 160 g of a 4-acetoxystyrene/1-ethylcyclopentyl methacrylate/monomer 1 copolymer (A-1).

To a reaction container, 10 g of the polymer obtained above, 40 mL of methanol, 200 mL of 1-methoxy-2-propanol, and 1.5 mL of concentrated hydrochloric acid were added, heated at 80° C., and stirred for 5 hours. The reaction solution was left to cool to room temperature, and added dropwise to 3L of distilled water. The solid obtained by filtration was dissolved in 200 mL of acetone, and added dropwise again to 3 L of distilled water; the solid obtained by filtration was dried under a reduced pressure to obtain a resin (A-1) (8.5 g). It was found to have a standard polystyrene-equivalent weight-average molecular weight (Mw) of 11200 as measured by gel permeation chromatography (GPC) (solvent: THF (tetrahydrofuran)) and a molecular-weight dispersity (Mw/Mn) of 1.45. The formula and the like will be described in Table 3 below.

TABLE 1

| | | Compositional ratio | | |
|---|---|---|---|---|
| | | (molar ratio) | | |
| | Structure | from the left | Mw | Mw/Mn |
| Resin A-1 | 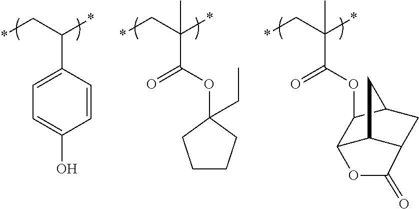 | 30/60/10 | 11.200 | 1.45 |

### Photoacid Generator (B)

As the photoacid generator, the following was used.

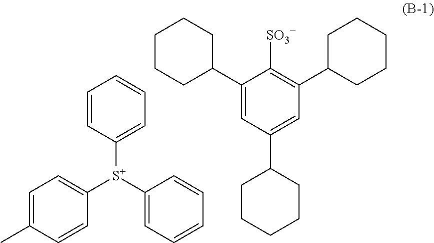

### Basic Compound (E)

As the basic compound, the following was used.

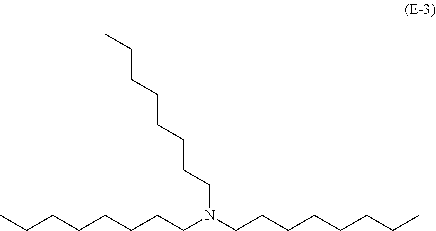 [SMILES: CCCCCCCCN(CCCCCCCC)CCCCCCCC]

The same method as above was also performed to evaluate generation of defects in the cases of using the chemical solutions (Examples 106 to 110 and Comparative Examples 106 to 110) as rinse solutions. As the developer, butyl acetate (nBA) used in Example 1 above was used.

### Evaluation of Metal Resist Developer

A method described below was performed to evaluate generation of defects in the cases of using the chemical solutions (Examples 51 to 105 and Comparative Examples 51 to 105) as metal resist developers.

First, monobutyl tin oxide hydrate (BuSnOOH) powder (0.209 g, TCI America) was added to 4-methyl-2-pentanol (10 mL), to prepare a metal resist precursor solution. The solution was placed into a sealed vial, and stirred for 24 hours. The resultant mixture was centrifuged at 4000 rpm for 15 minutes, and filtered through a 0.45 m PTFE (polytetrafluoroethylene) syringe filter to remove the insoluble material; thus, a metal resist composition R-1 was obtained.

Note that the organic solvent in the metal resist composition R-1 was removed and the solid content was fired at 600° C.; the Sn content was estimated on the basis of the mass of the remaining SnO₂ and, as a result, the Sn content in the metal resist composition R-1 was found to be 0.093 mol/L. In addition, a Moebius apparatus (Wyatt Technology) was used to subject the metal resist precursor solution to dynamic light scattering (DLS) analysis. The results matched with the unimodal distribution of particles having an average particle size of 2 nm and matched with the diameter reported on dodecamer butyl tin hydroxide oxide polyatomic cations (Eychenne-Baron et al., Organometallics, 19, 1940-1949 (2000)).

Subsequently, an undercoat film-forming composition SHB-A940 (manufactured by Shin-Etsu Chemical Co., Ltd.) was applied onto a silicon wafer having a diameter of 300 mm, and baked at 205° C. for 60 seconds, to form an undercoat film having a film thickness of 20 nm. Onto this, the metal resist composition R-1 was applied such that the dry film thickness would be 22 nm, and pre-baked at 100° C. for 90 seconds to form a metal resist film. In this way, a silicon wafer having a metal resist film was formed.

The silicon wafer having the metal resist film was subjected to pattern exposure using an EUV scanner NXE3400 (NA: 0.33, manufactured by ASML) while the exposure dose was changed. Note that the reticle employed was a hexagonal-array contact hole mask having a pitch of 36 nm and an opening size of 21 nm. Subsequently, the film was subjected to post-exposure baking (PEB) at 150° C. for 90 seconds and then to negative development by puddling for 30 seconds using the chemical solutions of Examples and Comparative Examples as the developers. After the development, the wafer was spin-dried at a rotation rate of 4000 rpm for 30 seconds, to obtain a pillar pattern having a pitch of 36 nm.

In the pillar pattern formed by the above-described procedures, as in the evaluation of the developer and the rinse solution, the number of particle defects and the number of pattern collapses were counted.

### Evaluation of Pre-Wet Solution

A method described below was performed to evaluate generation of defects in the cases of using the chemical solutions (Examples 21 to 25 and 111 to 120 and Comparative Examples 21 to 25 and 111 to 120) as pre-wet solutions. Note that the test was performed with a coater-developer “RF^{3S}” manufactured by SOKUDO Co., Ltd. The chemical solutions used for Examples 111 to 115 and Comparative Examples 111 to 115 were chemical solutions the same as the chemical solutions used for Examples 106 to 110 and Comparative Examples 106 to 110 used for the evaluation of the rinse solution. The chemical solutions used for Examples 116 to 120 and Comparative Examples 116 to 120 were chemical solutions the same as the chemical solutions used for Examples 16 to 20 and Comparative Examples 16 to 20 used for the evaluation of the rinse solution.

First, as in the evaluation of the developer and the rinse solution, a resist underlayer film having a film thickness of 20 nm was formed. Over this, the coater-developer was used to apply the chemical solution of each Examples as the pre-wet solution onto the silicon wafer. After the application of the chemical solution, the resist composition 1 used in the evaluation of the developer and the rinse solution was applied; coating unevenness of the resist was visually inspected and evaluated. Cases where unevenness was clearly observed were graded as B while cases where unevenness was not observed were graded as A.

As in the evaluation of the developer and the rinse solution, the number of particle defects after application of the resist was counted.

### Evaluation of Resist Washing Solution

A method described below was performed to evaluate generation of defects in the cases of using the chemical solutions (Examples 26 to 30 and Comparative Examples 26 to 30) as resist washing solutions.

As in the evaluation of the pre-wet solution, onto a silicon wafer having a resist underlayer film having a film thickness of 20 nm, a pre-wet solution (solvent mixture of PGMEA and propylene carbonate in 3:1) was applied and subsequently the resist composition 1 used for the evaluation of the developer and the rinse solution was applied, to form a resist film. The resist film formed had a film thickness of 30 nm.

The formed resist film was washed for 20 seconds by supplying the chemical solution as the resist washing solution. Subsequently, the silicon wafer was spin-dried at a rotation rate of 2000 rpm for 40 seconds.

For the washed and dried silicon wafer, X-ray photoelectron spectroscopy was performed to measure the carbon content of the surface of the silicon wafer. Also for an untreated silicon wafer, the carbon content of the surface was similarly measured. The measurement of the carbon content was performed for random 10 points on the silicon wafer and the average value was defined as the carbon content.

Cases where the carbon content of the washed and dried silicon wafer was 2 or more times the carbon content of the untreated silicon wafer were graded as B while cases where the carbon content of the washed and dried silicon wafer was less than 2 times the carbon content of the untreated silicon wafer were graded as A.

As in the evaluation of the developer and the rinse solution, the number of particle defects after the application of the resist was counted.

### Evaluation of Pipe Washing Solution

A method described below was performed to evaluate generation of defects in the cases of using the chemical solutions (Examples 31 to 50 and 121 to 125 and Comparative Examples 31 to 50 and 121 to 125) as pipe washing solutions. Note that the chemical solutions used for evaluation of the pipe washing solution were chemical solutions the same as the chemical solutions used for the evaluation of the developer and the rinse solution, the evaluation of the pre-wet solution, and the evaluation of the resist washing solution.

First, 7.57 L (2 gallons) of such a chemical solution was passed through a pipe (formed of PTFE) of a coater-developer “CLEAN TRACK LITHIUS PRO-Z” manufactured by Tokyo Electron Ltd., to wash the pipe. The chemical solution having been used for washing the pipe was recovered. Subsequently, a chemical solution of the same type as that of the chemical solution having been used for washing the pipe was applied to a silicon wafer through the pipe of the coater-developer. In other words, the chemical solution applied to the silicon wafer was a chemical solution of the same type as that of the chemical solution having been used for washing the pipe and was a chemical solution that was not the chemical solution having been used for washing the pipe and recovered.

For the silicon wafer coated with the chemical solution, the number of particle defects after application of the resist was counted as in the evaluation of the developer and the rinse solution.

### Results

Tables 2 to 16 will describe the results of the above-described evaluations.

In Tables 2 to 16, “Number of particle defects” means the number of defects per silicon wafer evaluated.

In Tables 2, 3 and 8 to 13, “Number of pattern collapses” means the number of defects per silicon wafer evaluated.

TABLE 2

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 2 | solvent | Material | (nm) | Material | (nm) | Material | (nm) | Material | (nm) | Material |
| Example 1 | nBA | IEX | — | Nylon | 5 | IEX | — | PTFE | 5 | IEX |
| Example 2 | nBA | IEX | — | PP | 5 | IEX | — | PTFE | 5 | IEX |
| Example 3 | nBA | IEX | — | Nylon | 10 | IEX | — | PTFE | 5 | IEX |
| Example 4 | nBA | IEX | — | Nylon | 5 | IEX | — | PP | 5 | IEX |
| Example 5 | nBA | IEX | — | Nylon | 10 | IEX | — | PTFE | 5 | IEX |
| Example 6 | MIBC | IEX | — | Nylon | 5 | IEX | — | PTFE | 5 | IEX |
| Example 7 | MIBC | IEX | — | PP | 5 | IEX | — | PTFE | 5 | IEX |
| Example 8 | MIBC | IEX | — | Nylon | 10 | IEX | — | PTFE | 5 | IEX |
| Example 9 | MIBC | IEX | — | Nylon | 5 | IEX | — | PP | 5 | IEX |
| Example 10 | MIBC | IEX | — | Nylon | 10 | IEX | — | PTFE | 5 | IEX |
| Comparative | nBA | PP | 200 | IEX | — | IEX | — | Nylon | 5 | UPE |
| Example 1 | | | | | | | | | | |
| Comparative | nBA | PP | 200 | IEX | — | IEX | — | Nylon | 5 | UPE |
| Example 2 | | | | | | | | | | |
| Comparative | nBA | PP | 200 | IEX | — | IEX | — | Nylon | 5 | UPE |
| Example 3 | | | | | | | | | | |
| Comparative | nBA | IEX | — | Nylon | 5 | IEX | — | PTFE | 5 | IEX |
| Example 4 | | | | | | | | | | |
| Comparative | nBA | IEX | — | Nylon | 5 | IEX | — | PTFE | 5 | IEX |
| Example 5 | | | | | | | | | | |
| Comparative | MIBC | PP | 200 | IEX | — | IEX | — | Nylon | 5 | UPE |
| Example 6 | | | | | | | | | | |
| Comparative | MIBC | PP | 200 | IEX | — | IEX | — | Nylon | 5 | UPE |
| Example 7 | | | | | | | | | | |
| Comparative | MIBC | PP | 200 | IEX | — | IEX | — | Nylon | 5 | UPE |
| Example 8 | | | | | | | | | | |
| Comparative | MIBC | IEX | — | Nylon | 5 | IEX | — | PTFE | 5 | IEX |
| Example 9 | | | | | | | | | | |
| Comparative | MIBC | IEX | — | Nylon | 5 | IEX | — | PTFE | 5 | IEX |
| Example 10 | | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 2 | (nm) | Material | (nm) | circulations | (counts/mm²) | defects | (/wafer) |
| Example 1 | — | UPE | 3 | 2 | 0.011 | 4 | 9 |
| Example 2 | — | UPE | 3 | 2 | 0.030 | 8 | 3 |
| Example 3 | — | UPE | 3 | 2 | 0.990 | 8 | 6 |
| Example 4 | — | UPE | 3 | 2 | 0.170 | 6 | 5 |
| Example 5 | — | UPE | 3 | 1 | 9.791 | 12 | 5 |
| Example 6 | — | UPE | 3 | 2 | 0.010 | 1 | 6 |
| Example 7 | — | UPE | 3 | 2 | 0.039 | 5 | 3 |
| Example 8 | — | UPE | 3 | 2 | 1.170 | 11 | 6 |
| Example 9 | — | UPE | 3 | 2 | 0.210 | 9 | 1 |
| Example 10 | — | UPE | 3 | 1 | 9.875 | 15 | 1 |
| Comparative | 3 | | | 3 | 3659.131 | 72 | 11 |
| Example 1 | | | | | | | |
| Comparative | 3 | | | 15 | 18.381 | 57 | 11 |
| Example 2 | | | | | | | |
| Comparative | 3 | | | 18 | 11.135 | 51 | 10 |
| Example 3 | | | | | | | |
| Comparative | — | UPE | 3 | 10 | 0.007 | 1 | 186 |
| Example 4 | | | | | | | |
| Comparative | — | UPE | 3 | 15 | 0.001 | 2 | 837 |
| Example 5 | | | | | | | |
| Comparative | 3 | | | 3 | 7818.198 | 99 | 15 |
| Example 6 | | | | | | | |
| Comparative | 3 | | | 15 | 15.298 | 51 | 15 |
| Example 7 | | | | | | | |
| Comparative | 3 | | | 18 | 12.087 | 47 | 14 |
| Example 8 | | | | | | | |
| Comparative | — | UPE | 3 | 10 | 0.009 | 3 | 295 |
| Example 9 | | | | | | | |
| Comparative | — | UPE | 3 | 15 | 0.003 | 5 | 798 |
| Example 10 | | | | | | | |

TABLE 3

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 3 | solvent | Material | (nm) | Material | (nm) | Material | (nm) | Material | (nm) | Material |
| Example 11 | nBA | IEX | — | Nylon | 5 | IEX | — | PTFE | 5 | IEX |
| Example 12 | nBA | IEX | — | PP | 5 | IEX | — | PTFE | 5 | IEX |
| Example 13 | nBA | IEX | — | Nylon | 10 | IEX | — | PTFE | 5 | IEX |
| Example 14 | nBA | IEX | — | Nylon | 5 | IEX | — | PP | 5 | IEX |
| Example 15 | nBA | IEX | — | Nylon | 10 | IEX | — | PTFE | 5 | IEX |
| Example 16 | MIBC | IEX | — | Nylon | 5 | IEX | — | PTFE | 5 | IEX |
| Example 17 | MIBC | IEX | — | PP | 5 | IEX | — | PTFE | 5 | IEX |
| Example 18 | MIBC | IEX | — | Nylon | 10 | IEX | — | PTFE | 5 | IEX |
| Example 19 | MIBC | IEX | — | Nylon | 5 | IEX | — | PP | 5 | IEX |
| Example 20 | MIBC | IEX | — | Nylon | 10 | IEX | — | PTFE | 5 | IEX |
| Comparative | nBA | PP | 200 | IEX | — | IEX | — | Nylon | 5 | UPE |
| Example 11 | | | | | | | | | | |
| Comparative | nBA | PP | 200 | IEX | — | IEX | — | Nylon | 5 | UPE |
| Example 12 | | | | | | | | | | |
| Comparative | nBA | PP | 200 | IEX | — | IEX | — | Nylon | 5 | UPE |
| Example 13 | | | | | | | | | | |
| Comparative | nBA | IEX | — | Nylon | 5 | IEX | — | PTFE | 5 | IEX |
| Example 14 | | | | | | | | | | |
| Comparative | nBA | IEX | — | Nylon | 5 | IEX | — | PTFE | 5 | IEX |
| Example 15 | | | | | | | | | | |
| Comparative | MIBC | PP | 200 | IEX | — | IEX | — | Nylon | 5 | UPE |
| Example 16 | | | | | | | | | | |
| Comparative | MIBC | PP | 200 | IEX | — | IEX | — | Nylon | 5 | UPE |
| Example 17 | | | | | | | | | | |
| Comparative | MIBC | PP | 200 | IEX | — | IEX | — | Nylon | 5 | UPE |
| Example 18 | | | | | | | | | | |
| Comparative | MIBC | IEX | — | Nylor | 5 | IEX | — | PTFE | 5 | IEX |
| Example 19 | | | | | | | | | | |
| Comparative | MIBC | IEX | — | Nylon | 5 | IEX | — | PTFE | 5 | IEX |
| Example 20 | | | | | | | | | | |

| | | | | | | Wafer evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 3 | (nm) | Material | (nm) | circulations | (counts/mm²) | defects | (/wafer) |
| Example 11 | — | UPE | 3 | 2 | 0.011 | 5 | 11 |
| Example 12 | — | UPE | 3 | 2 | 0.030 | 9 | 6 |
| Example 13 | — | UPE | 3 | 2 | 0.990 | 8 | 7 |
| Example 14 | — | UPE | 3 | 2 | 0.170 | 5 | 5 |
| Example 15 | — | UPE | 3 | 1 | 9.791 | 13 | 6 |
| Example 16 | — | UPE | 3 | 2 | 0.010 | 2 | 8 |
| Example 17 | — | UPE | 3 | 2 | 0.039 | 4 | 5 |
| Example 18 | — | UPE | 3 | 2 | 1.170 | 13 | 7 |
| Example 19 | — | UPE | 3 | 2 | 0.210 | 10 | 3 |
| Example 20 | — | UPE | 3 | 1 | 9.875 | 13 | 5 |
| Comparative | 3 | | | 3 | 3659.131 | 82 | 13 |
| Example 11 | | | | | | | |
| Comparative | 3 | | | 15 | 18.381 | 60 | 14 |
| Example 12 | | | | | | | |
| Comparative | 3 | | | 18 | 11.135 | 56 | 14 |
| Example 13 | | | | | | | |
| Comparative | — | UPE | 3 | 10 | 0.007 | 3 | 199 |
| Example 14 | | | | | | | |
| Comparative | — | UPE | 3 | 15 | 0.001 | 5 | 965 |
| Example 15 | | | | | | | |
| Comparative | 3 | | | 3 | 7818.198 | 111 | 19 |
| Example 16 | | | | | | | |
| Comparative | 3 | | | 15 | 15.298 | 62 | 17 |
| Example 17 | | | | | | | |
| Comparative | 3 | | | 18 | 12.087 | 39 | 16 |
| Example 18 | | | | | | | |
| Comparative | — | UPE | 3 | 10 | 0.009 | 5 | 316 |
| Example 19 | | | | | | | |
| Comparative | — | UPE | 3 | 15 | 0.003 | 7 | 811 |
| Example 20 | | | | | | | |

TABLE 4

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 4 | solvent | Material | (nm) | Material | (nm) | Material | (nm) | Material | (nm) | Material |
| Example 21 | CHN | IEX | — | Nylon | 5 | IEX | — | PTFE | 5 | IEX |
| Example 22 | CHN | IEX | — | PP | 5 | IEX | — | PTFE | 5 | IEX |
| Example 23 | CHN | IEX | — | Nylon | 10 | IEX | — | PTFE | 5 | IEX |
| Example 24 | CHN | IEX | — | Nylon | 5 | IEX | — | PP | 5 | IEX |
| Example 25 | CHN | IEX | — | Nylon | 10 | IEX | — | PTFE | 5 | IEX |
| Comparative | CHN | PP | 200 | IEX | — | IEX | — | Nylon | 5 | UPE |
| Example 21 | | | | | | | | | | |
| Comparative | CHN | PP | 200 | IEX | — | IEX | — | Nylon | 5 | UPE |
| Example 22 | | | | | | | | | | |
| Comparative | CHN | PP | 200 | IEX | — | IEX | — | Nylon | 5 | UPE |
| Example 23 | | | | | | | | | | |
| Comparative | CHN | IEX | — | Nylon | 5 | IEX | — | PTFE | 5 | IEX |
| Example 24 | | | | | | | | | | |
| Comparative | CHN | IEX | — | Nylon | 5 | IEX | — | PTFE | 5 | IEX |
| Example 25 | | | | | | | | | | |

| | Fifth filter | Sixth filter | | | Analysis | Wafer evaluation | |
|---|---|---|---|---|---|---|---|
| | Pore | | Pore | | result | Number of | Resist |
| | size | | size | Number of | I value | particle | coating |
| Table 4 | (nm) | Material | (nm) | circulations | (counts/mm²) | defects | unevenness |
| Example 21 | — | UPE | 3 | 2 | 0.019 | 9 | A |
| Example 22 | — | UPE | 3 | 2 | 0.610 | 9 | A |
| Example 23 | — | UPE | 3 | 2 | 2.112 | 14 | A |
| Example 24 | — | UPE | 3 | 2 | 0.179 | 8 | A |
| Example 25 | — | UPE | 3 | 1 | 9.589 | 17 | A |
| Comparative | 3 | | | 3 | 3659.131 | 81 | A |
| Example 21 | | | | | | | |
| Comparative | 3 | | | 15 | 14.389 | 51 | A |
| Example 22 | | | | | | | |
| Comparative | 3 | | | 18 | 11.917 | 45 | A |
| Example 23 | | | | | | | |
| Comparative | — | UPE | 3 | 10 | 0.009 | 2 | B |
| Example 24 | | | | | | | |
| Comparative | — | UPE | 3 | 15 | 0.001 | 1 | B |
| Example 25 | | | | | | | |

TABLE 5

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 5 | solvent | Material | (nm) | Material | (nm) | Material | (nm) | Material | (nm) | Material |
| Example 26 | PGMEA | IEX | — | Nylon | 5 | IEX | — | PTFE | 5 | IEX |
| Example 27 | PGMEA | IEX | — | PP | 5 | IEX | — | PTFE | 5 | IEX |
| Example 28 | PGEMA | IEX | — | Nylon | 10 | IEX | — | PTFE | 5 | IEX |
| Example 29 | PGEMA | IEX | — | Nylon | 5 | IEX | — | PP | 5 | IEX |
| Example 30 | PGEMA | IEX | — | Nylon | 10 | IEX | — | PTFE | 5 | IEX |
| Comparative | PGMEA | PP | 200 | IEX | — | IEX | — | Nylon | 5 | UPE |
| Example 26 | | | | | | | | | | |
| Comparative | PGMEA | PP | 200 | IEX | — | IEX | — | Nylon | 5 | UPE |
| Example 27 | | | | | | | | | | |
| Comparative | PGMEA | PP | 200 | IEX | — | IEX | — | Nylon | 5 | UPE |
| Example 28 | | | | | | | | | | |
| Comparative | PGMEA | IEX | — | Nylon | 5 | IEX | — | PTFE | 5 | IEX |
| Example 29 | | | | | | | | | | |
| Comparative | PGMEA | IEX | — | Nylon | 5 | IEX | — | PTFE | 5 | IEX |
| Example 30 | | | | | | | | | | |

| | Fifth filter | Sixth filter | | | Analysis | Wafer evaluation | |
|---|---|---|---|---|---|---|---|
| | Pore | | Pore | | result | Number of | Evaluation |
| | size | | size | Number of | I value | particle | of resist |
| Table 5 | (nm) | Material | (nm) | circulations | (counts/mm²) | defects | scum |
| Example 26 | — | UPE | 3 | 2 | 0.021 | 13 | A |
| Example 27 | — | UPE | 3 | 2 | 0.580 | 14 | A |
| Example 28 | — | UPE | 3 | 2 | 2.319 | 17 | A |
| Example 29 | — | UPE | 3 | 2 | 0.879 | 14 | A |
| Example 30 | — | UPE | 3 | 1 | 9.233 | 18 | A |
| Comparative | 3 | | | 3 | 4120.185 | 119 | A |
| Example 26 | | | | | | | |
| Comparative | 3 | | | 15 | 16.000 | 45 | A |
| Example 27 | | | | | | | |
| Comparative | 3 | | | 18 | 12.176 | 43 | A |
| Example 28 | | | | | | | |
| Comparative | — | UPE | 3 | 10 | 0.008 | 19 | B |
| Example 29 | | | | | | | |
| Comparative | — | UPE | 3 | 15 | 0.001 | 5 | B |
| Example 30 | | | | | | | |

TABLE 6

| | Purification- | | | | | | | | |
|---|---|---|---|---|---|---|---|---|---|
| | target | First filter | | Second filter | | Third filter | | Fourth filter | |
| | substance | | Pore | | Pore | | Pore | | Pore |
| | Organic | | size | | size | | size | | size |
| Table 6 | solvent | Material | (nm) | Material | (nm) | Material | (nm) | Material | (nm) |
| Example 31 | PGMEA | IEX | — | Nylon | 5 | IEX | — | PTFE | 5 |
| Example 32 | PGMEA | IEX | — | PP | 5 | IEX | — | PTFE | 5 |
| Example 33 | PGEMA | IEX | — | Nylon | 10 | IEX | — | PTFE | 5 |
| Example 34 | PGEMA | IEX | — | Nylon | 5 | IEX | — | PP | 5 |
| Example 35 | PGEMA | IEX | — | Nylon | 5 | IEX | — | PP | 5 |
| Example 36 | nBA | IEX | — | Nylon | 5 | IEX | — | PTFE | 5 |
| Example 37 | nBA | IEX | — | PP | 5 | IEX | — | PTFE | 5 |
| Example 38 | nBA | IEX | — | Nylon | 10 | IEX | — | PTFE | 5 |
| Example 39 | nBA | IEX | — | Nylon | 5 | IEX | — | PP | 5 |
| Example 40 | nBA | IEX | — | Nylon | 10 | IEX | — | PTFE | 5 |
| Example 41 | MIBC | IEX | — | Nylon | 5 | IEX | — | PTFE | 5 |
| Example 42 | MIBC | IEX | — | PP | 5 | IEX | — | PTFE | 5 |
| Example 43 | MIBC | IEX | — | Nylon | 10 | IEX | — | PTFE | 5 |
| Example 44 | MIBC | IEX | — | Nylon | 5 | IEX | — | PP | 5 |
| Example 45 | MIBC | IEX | — | Nylon | 10 | IEX | — | PTFE | 5 |
| Example 46 | CHN | IEX | — | Nylon | 5 | IEX | — | PTFE | 5 |
| Example 47 | CHN | IEX | — | PP | 5 | IEX | — | PTFE | 5 |
| Example 48 | CHN | IEX | — | Nylon | 10 | IEX | — | PTFE | 5 |
| Example 49 | CHN | IEX | — | Nylon | 5 | IEX | — | PP | 5 |
| Example 50 | CHN | IEX | — | Nylon | 10 | IEX | — | PTFE | 5 |

| | Fifth filter | | Sixth filter | | | Analysis | |
|---|---|---|---|---|---|---|---|
| | | Pore | | Pore | | result | Number of |
| | | size | | size | Number of | I value | particle |
| Table 6 | Material | (nm) | Material | (nm) | circulations | (counts/mm²) | defects |
| Example 31 | IEX | — | UPE | 3 | 2 | 0.021 | 13 |
| Example 32 | IEX | — | UPE | 3 | 2 | 0.580 | 14 |
| Example 33 | IEX | — | UPE | 3 | 2 | 2.319 | 17 |
| Example 34 | IEX | — | UPE | 3 | 2 | 0.879 | 14 |
| Example 35 | IEX | — | UPE | 3 | 1 | 9.233 | 18 |
| Example 36 | IEX | — | UPE | 3 | 2 | 0.011 | 9 |
| Example 37 | IEX | — | UPE | 3 | 2 | 0.030 | 3 |
| Example 38 | IEX | — | UPE | 3 | 2 | 0.990 | 2 |
| Example 39 | IEX | — | UPE | 3 | 2 | 0.170 | 6 |
| Example 40 | IEX | — | UPE | 3 | 1 | 9.791 | 10 |
| Example 41 | IEX | — | UPE | 3 | 2 | 0.010 | 6 |
| Example 42 | IEX | — | UPE | 3 | 2 | 0.039 | 5 |
| Example 43 | IEX | — | UPE | 3 | 2 | 1.170 | 11 |
| Example 44 | IEX | — | UPE | 3 | 2 | 0.210 | 9 |
| Example 45 | IEX | — | UPE | 3 | 1 | 9.875 | 14 |
| Example 46 | IEX | — | UPE | 3 | 2 | 0.019 | 8 |
| Example 47 | IEX | — | UPE | 3 | 2 | 0.610 | 8 |
| Example 48 | IEX | — | UPE | 3 | 2 | 2.112 | 14 |
| Example 49 | IEX | — | UPE | 3 | 2 | 0.179 | 9 |
| Example 50 | IEX | — | UPE | 3 | 1 | 9.589 | 17 |

TABLE 7

| | Purification- | | | | | | | | |
|---|---|---|---|---|---|---|---|---|---|
| | target | First filter | | Second filter | | Third filter | | Fourth filter | |
| | substance | | Pore | | Pore | | Pore | | Pore |
| | Organic | | size | | size | | size | | size |
| Table 7 | solvent | Material | (nm) | Material | (nm) | Material | (nm) | Material | (nm) |
| Comparative | PGMEA | PP | 200 | IEX | — | IEX | — | Nylon | 5 |
| Example 31 | | | | | | | | | |
| Comparative | PGMEA | PP | 200 | IEX | — | IEX | — | Nylon | 5 |
| Example 32 | | | | | | | | | |
| Comparative | PGMEA | PP | 200 | IEX | — | IEX | — | Nylon | 5 |
| Example 33 | | | | | | | | | |
| Comparative | PGMEA | IEX | — | Nylon | 5 | IEX | — | PTFE | 5 |
| Example 34 | | | | | | | | | |
| Comparative | PGMEA | IEX | — | Nylon | 5 | IEX | — | PTFE | 5 |
| Example 35 | | | | | | | | | |
| Comparative | nBA | PP | 200 | IEX | — | IEX | — | Nylon | 5 |
| Example 36 | | | | | | | | | |
| Comparative | nBA | PP | 200 | IEX | — | IEX | — | Nylon | 5 |
| Example 37 | | | | | | | | | |
| Comparative | nBA | PP | 200 | IEX | — | IEX | — | Nylon | 5 |
| Example 38 | | | | | | | | | |
| Comparative | nBA | IEX | — | Nylon | 5 | IEX | — | PTFE | 5 |
| Example 39 | | | | | | | | | |
| Comparative | nBA | IEX | — | Nylon | 5 | IEX | — | PTFE | 5 |
| Example 40 | | | | | | | | | |
| Comparative | MIBC | PP | 200 | IEX | — | IEX | — | Nylon | 5 |
| Example 41 | | | | | | | | | |
| Comparative | MIBC | PP | 200 | IEX | — | IEX | — | Nylon | 5 |
| Example 42 | | | | | | | | | |
| Comparative | MIBC | PP | 200 | IEX | — | IEX | — | Nylon | 5 |
| Example 43 | | | | | | | | | |
| Comparative | MIBC | IEX | — | Nylon | 5 | IEX | — | PTFE | 5 |
| Example 44 | | | | | | | | | |
| Comparative | MIBC | IEX | — | Nylon | 5 | IEX | — | PTFE | 5 |
| Example 45 | | | | | | | | | |
| Comparative | CHN | PP | 200 | IEX | — | IEX | — | Nylon | 5 |
| Example 46 | | | | | | | | | |
| Comparative | CHN | PP | 200 | IEX | — | IEX | — | Nylon | 5 |
| Example 47 | | | | | | | | | |
| Comparative | CHN | PP | 200 | IEX | — | IEX | — | Nylon | 5 |
| Example 48 | | | | | | | | | |
| Comparative | CHN | IEX | — | Nylon | 5 | IEX | — | PTFE | 5 |
| Example 49 | | | | | | | | | |
| Comparative | CHN | IEX | — | Nylon | 5 | IEX | — | PTFE | 5 |
| Example 50 | | | | | | | | | |

| | Fifth filter | | Sixth filter | | | Analysis | |
|---|---|---|---|---|---|---|---|
| | | Pore | | Pore | | result | Number of |
| | | size | | size | Number of | I value | particle |
| Table 7 | Material | (nm) | Material | (nm) | circulations | (counts/mm²) | defects |
| Comparative | UPE | 3 | | | 3 | 4120.185 | 131 |
| Example 31 | | | | | | | |
| Comparative | UPE | 3 | | | 15 | 16.000 | 61 |
| Example 32 | | | | | | | |
| Comparative | UPE | 3 | | | 18 | 12.176 | 57 |
| Example 33 | | | | | | | |
| Comparative | IEX | — | UPE | 3 | 10 | 0.008 | 59 |
| Example 34 | | | | | | | |
| Comparative | IEX | — | UPE | 3 | 15 | 0.001 | 95 |
| Example 35 | | | | | | | |
| Comparative | UPE | 3 | | | 3 | 3659.131 | 211 |
| Example 36 | | | | | | | |
| Comparative | UPE | 3 | | | 15 | 18.381 | 48 |
| Example 37 | | | | | | | |
| Comparative | UPE | 3 | | | 18 | 11.135 | 43 |
| Example 38 | | | | | | | |
| Comparative | IEX | — | UPE | 3 | 10 | 0.007 | 68 |
| Example 39 | | | | | | | |
| Comparative | IEX | — | UPE | 3 | 15 | 0.001 | 99 |
| Example 40 | | | | | | | |
| Comparative | UPE | 3 | | | 3 | 7818.198 | 109 |
| Example 41 | | | | | | | |
| Comparative | UPE | 3 | | | 15 | 15.298 | 61 |
| Example 42 | | | | | | | |
| Comparative | UPE | 3 | | | 18 | 12.087 | 45 |
| Example 43 | | | | | | | |
| Comparative | IEX | — | UPE | 3 | 10 | 0.009 | 43 |
| Example 44 | | | | | | | |
| Comparative | IEX | — | UPE | 3 | 15 | 0.003 | 77 |
| Example 45 | | | | | | | |
| Comparative | UPE | 3 | | | 3 | 3659.131 | 98 |
| Example 46 | | | | | | | |
| Comparative | UPE | 3 | | | 15 | 14.389 | 57 |
| Example 47 | | | | | | | |
| Comparative | UPE | 3 | | | 18 | 11.917 | 51 |
| Example 48 | | | | | | | |
| Comparative | IEX | — | UPE | 3 | 10 | 0.009 | 41 |
| Example 49 | | | | | | | |
| Comparative | IEX | — | UPE | 3 | 15 | 0.001 | 66 |
| Example 50 | | | | | | | |

TABLE 8

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 8 | solvent | Material | (nm) | Material | (nm) | Material | (nm) | Material | (nm) | Material |
| Example 51 | PGMEA80/ | IEX | — | Nylon | 5 | IEX | — | PTFE | 5 | IEX |
| | Acetic acid20 | | | | | | | | | |
| Example 52 | PGMEA80/ | IEX | — | PP | 5 | IEX | — | PTFE | 5 | IEX |
| | Acetic acid20 | | | | | | | | | |
| Example 53 | PGMEA80/ | IEX | — | Nylon | 10 | IEX | — | PTFE | 5 | IEX |
| | Acetic acid20 | | | | | | | | | |
| Example 54 | PGMEA80/ | IEX | — | Nylon | 5 | IEX | — | PP | 5 | IEX |
| | Acetic acid20 | | | | | | | | | |
| Example 55 | PGMEA80/ | IEX | — | Nylon | 10 | IEX | — | PTFE | 5 | IEX |
| | Acetic acid20 | | | | | | | | | |
| Comparative | PGMEA80/ | PP | 200 | IEX | — | IEX | — | Nylon | 5 | UPE |
| Example 51 | Acetic acid20 | | | | | | | | | |
| Comparative | PGMEA80/ | PP | 200 | IEX | — | IEX | — | Nylon | 5 | UPE |
| Example 52 | Acetic acid20 | | | | | | | | | |
| Comparative | PGMEA80/ | PP | 200 | IEX | — | IEX | — | Nylon | 5 | UPE |
| Example 53 | Acetic acid20 | | | | | | | | | |
| Comparative | PGMEA80/ | IEX | — | Nylon | 5 | IEX | — | PTFE | 5 | IEX |
| Example 54 | Acetic acid20 | | | | | | | | | |
| Comparative | PGMEA80/ | IEX | — | Nylon | 5 | IEX | — | PTFE | 5 | IEX |
| Example 55 | Acetic acid20 | | | | | | | | | |
| Example 56 | PGMEA85/ | IEX | — | Nylon | 5 | IEX | — | PTFE | 5 | IEX |
| | Acetic acid15 | | | | | | | | | |
| Example 57 | PGMEA85/ | IEX | — | PP | 5 | IEX | — | PTFE | 5 | IEX |
| | Acetic acid15 | | | | | | | | | |
| Example 58 | PGMEA85/ | IEX | — | Nylon | 10 | IEX | — | PTFE | 5 | IEX |
| | Acetic acid15 | | | | | | | | | |
| Example 59 | PGMEA85/ | IEX | — | Nylon | 5 | IEX | — | PP | 5 | IEX |
| | Acetic acid15 | | | | | | | | | |
| Example 60 | PGMEA85/ | IEX | — | Nylon | 10 | IEX | — | PTFE | 5 | IEX |
| | Acetic acid15 | | | | | | | | | |
| Comparative | PGMEA85/ | PP | 200 | IEX | — | IEX | — | Nylon | 5 | UPE |
| Example 56 | Acetic acid15 | | | | | | | | | |
| Comparative | PGMEA85/ | PF | 200 | IEX | — | IEX | — | Nylon | 5 | UPE |
| Example 57 | Acetic acid15 | | | | | | | | | |
| Comparative | PGMEA85/ | PF | 200 | IEX | — | IEX | — | Nylon | 5 | UPE |
| Example 58 | Acetic acid15 | | | | | | | | | |
| Comparative | PGMEA85/ | IEX | — | Nylon | 5 | IEX | — | PTFE | 5 | IEX |
| Example 59 | Acetic acid15 | | | | | | | | | |
| Comparative | PGMEA85/ | IEX | — | Nylon | 5 | IEX | — | PTFE | 5 | IEX |
| Example 60 | Acetic acid15 | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 8 | (nm) | Material | (nm) | circulations | (counts/mm²) | defects | (/wafer) |
| Example 51 | — | UPE | 3 | 2 | 0.011 | 4 | 7 |
| Example 52 | — | UPE | 3 | 2 | 0.033 | 6 | 2 |
| Example 53 | — | UPE | 3 | 2 | 0.914 | 11 | 2 |
| Example 54 | — | UPE | 3 | 2 | 0.110 | 10 | 5 |
| Example 55 | — | UPE | 3 | 1 | 9.980 | 17 | 6 |
| Comparative | 3 | | | 3 | 2794.251 | 99 | 10 |
| Example 51 | | | | | | | |
| Comparative | 3 | | | 15 | 17.785 | 57 | 16 |
| Example 52 | | | | | | | |
| Comparative | 3 | | | 18 | 12.869 | 52 | 5 |
| Example 53 | | | | | | | |
| Comparative | — | UPE | 3 | 10 | 0.004 | 4 | 211 |
| Example 54 | | | | | | | |
| Comparative | — | UPE | 3 | 15 | 0.002 | 2 | 987 |
| Example 55 | | | | | | | |
| Example 56 | — | UPE | 3 | 2 | 0.014 | 4 | 8 |
| Example 57 | — | UPE | 3 | 2 | 0.034 | 6 | 2 |
| Example 58 | — | UPE | 3 | 2 | 1.086 | 8 | 4 |
| Example 59 | — | UPE | 3 | 2 | 0.108 | 7 | 5 |
| Example 60 | — | UPE | 3 | 1 | 9.911 | 12 | 4 |
| Comparative | 3 | | | 3 | 2926.035 | 88 | 11 |
| Example 56 | | | | | | | |
| Comparative | 3 | | | 15 | 17.851 | 55 | 11 |
| Example 57 | | | | | | | |
| Comparative | — | | | 18 | 14.247 | 50 | 10 |
| Example 58 | | | | | | | |
| Comparative | — | UPE | 3 | 10 | 0.006 | 4 | 210 |
| Example 59 | | | | | | | |
| Comparative | — | UPE | 3 | 15 | 0.002 | 3 | 928 |
| Example 60 | | | | | | | |

TABLE 9

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 9 | solvent | Material | (nm) | Material | (nm) | Material | (nm) | Material | (nm) | Material |
| Example 61 | PGMEA90/ | IEX | — | Nylon | 5 | IEX | — | PTFE | 5 | IEX |
| | Acetic acid10 | | | | | | | | | |
| Example 62 | PGMEA90/ | IEX | — | PP | 5 | IEX | — | PTFE | 5 | IEX |
| | Acetic acid10 | | | | | | | | | |
| Example 63 | PGMEA90/ | IEX | — | Nylon | 10 | IEX | — | PTFE | 5 | IEX |
| | Acetic acid10 | | | | | | | | | |
| Example 64 | PGMEA90/ | IEX | — | Nylon | 5 | IEX | — | PF | 5 | IEX |
| | Acetic acid10 | | | | | | | | | |
| Example 65 | PGMEA90/ | IEX | — | Nylon | 10 | IEX | — | PTFE | 5 | IEX |
| | Acetic acid10 | | | | | | | | | |
| Comparative | PGMEA90/ | PP | 200 | IEX | — | IEX | — | Nylon | 5 | UPE |
| Example 61 | Acetic acid10 | | | | | | | | | |
| Comparative | PGMEA90/ | PP | 200 | IEX | — | IEX | — | Nylon | 5 | UPE |
| Example 62 | Acetic acid10 | | | | | | | | | |
| Comparative | PGMEA90/ | PP | 200 | IEX | — | IEX | — | Nylon | 5 | UPE |
| Example 63 | Acetic acid10 | | | | | | | | | |
| Comparative | PGMEA90/ | IEX | — | Nylon | 5 | IEX | — | PTFE | 5 | IEX |
| Example 64 | Acetic acid10 | | | | | | | | | |
| Comparative | PGMEA90/ | IEX | — | Nylon | 5 | IEX | — | PTFE | 5 | IEX |
| Example 65 | Acetic acid10 | | | | | | | | | |
| Example 66 | PGMEA99/ | IEX | — | Nylon | 5 | IEX | — | PTFE | 5 | IEX |
| | Acetic acid1 | | | | | | | | | |
| Example 67 | PGMEA99/ | IEX | — | PP | 5 | IEX | — | PTFE | 5 | IEX |
| | Acetic acid1 | | | | | | | | | |
| Example 68 | PGMEA99/ | IEX | — | Nylon | 10 | IEX | — | PTFE | 5 | IEX |
| | Acetic acid1 | | | | | | | | | |
| Example 69 | PGMEA99/ | IEX | — | Nylon | 5 | IEX | — | PF | 5 | IEX |
| | Acetic acid1 | | | | | | | | | |
| Example 70 | PGMEA99/ | IEX | — | Nylon | 10 | IEX | — | PTFE | 5 | IEX |
| | Acetic acid1 | | | | | | | | | |
| Comparative | PGMEA99/ | PF | 200 | IEX | — | IEX | — | Nylon | 5 | UPE |
| Example 66 | Acetic acid1 | | | | | | | | | |
| Comparative | PGMEA99/ | PF | 200 | IEX | — | IEX | — | Nylon | 5 | UPE |
| Example 67 | Acetic acid1 | | | | | | | | | |
| Comparative | PGMEA99/ | PP | 200 | IEX | — | IEX | — | Nylon | 5 | UPE |
| Example 68 | Acetic acid1 | | | | | | | | | |
| Comparative | PGMEA99/ | IEX | — | Nylon | 5 | IEX | — | PTFE | 5 | IEX |
| Example 69 | Acetic acid1 | | | | | | | | | |
| Comparative | PGMEA99/ | IEX | — | Nylon | 5 | IEX | — | PTFE | 5 | IEX |
| Example 70 | Acetic acid1 | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 9 | (nm) | Material | (nm) | circulations | (counts/mm²) | defects | (/wafer) |
| Example 61 | — | UPE | 3 | 2 | 0.011 | 3 | 10 |
| Example 62 | — | UPE | 3 | 2 | 0.038 | 5 | 6 |
| Example 63 | — | UPE | 3 | 2 | 1.004 | 12 | 3 |
| Example 64 | — | UPE | 3 | 2 | 0.161 | 7 | 4 |
| Example 65 | — | UPE | 3 | 1 | 9.102 | 16 | 2 |
| Comparative | 3 | | | 3 | 1846.876 | 98 | 10 |
| Example 61 | | | | | | | |
| Comparative | 3 | | | 15 | 38.633 | 52 | 9 |
| Example 62 | | | | | | | |
| Comparative | 3 | | | 18 | 11.828 | 55 | 11 |
| Example 63 | | | | | | | |
| Comparative | — | UPE | 3 | 10 | 0.003 | 3 | 301 |
| Example 64 | | | | | | | |
| Comparative | — | UPE | 3 | 15 | 0.001 | 5 | 1034 |
| Example 65 | | | | | | | |
| Example 66 | — | UPE | 3 | 2 | 0.010 | 3 | 12 |
| Example 67 | — | UPE | 3 | 2 | 0.034 | 7 | 7 |
| Example 68 | — | UPE | 3 | 2 | 1.073 | 7 | 4 |
| Example 69 | — | UPE | 3 | 2 | 0.165 | 9 | 5 |
| Example 70 | — | UPE | 3 | 1 | 9.520 | 11 | 2 |
| Comparative | 3 | | | 3 | 1819.727 | 118 | 15 |
| Example 66 | | | | | | | |
| Comparative | 3 | | | 15 | 36.953 | 80 | 13 |
| Example 67 | | | | | | | |
| Comparative | 3 | | | 18 | 12.445 | 73 | 7 |
| Example 68 | | | | | | | |
| Comparative | — | UPE | 3 | 10 | 0.003 | 3 | 244 |
| Example 69 | | | | | | | |
| Comparative | — | UPE | 3 | 15 | 0.001 | 3 | 1270 |
| Example 70 | | | | | | | |

TABLE 10

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 10 | solvent | Material | (nm) | Material | (nm) | Material | (nm) | Material | (nm) | Material |
| Example 71 | PGMEA90/ | IEX | — | Nylon | 5 | IEX | — | PTFE | 5 | IEX |
| | Formic acid10 | | | | | | | | | |
| Example 72 | PGMEA90/ | IEX | — | PP | 5 | IEX | — | PTFE | 5 | IEX |
| | Formic acid10 | | | | | | | | | |
| Example 73 | PGMEA90/ | IEX | — | Nylon | 10 | IEX | — | PTFE | 5 | IEX |
| | Formic acid10 | | | | | | | | | |
| Example 74 | PGMEA90/ | IEX | — | Nylon | 5 | IEX | — | PP | 5 | IEX |
| | Formic acid10 | | | | | | | | | |
| Example 75 | PGMEA90/ | IEX | — | Nylon | 10 | IEX | — | PTFE | 5 | IEX |
| | Formic acid10 | | | | | | | | | |
| Comparative | PGMEA90/ | PP | 200 | IEX | — | IEX | — | Nylon | 5 | UPE |
| Example 71 | Formic acid10 | | | | | | | | | |
| Comparative | PGMEA90/ | PP | 200 | IEX | — | IEX | — | Nylon | 5 | UPE |
| Example 72 | Formic acid10 | | | | | | | | | |
| Comparative | PGMEA90/ | PP | 200 | IEX | — | IEX | — | Nylon | 5 | UPE |
| Example 73 | Formic acid10 | | | | | | | | | |
| Comparative | PGMEA90/ | IEX | — | Nylon | 5 | IEX | — | PTFE | 5 | IEX |
| Example 74 | Formic acid10 | | | | | | | | | |
| Comparative | PGMEA90/ | IEX | — | Nylon | 5 | IEX | — | PTFE | 5 | IEX |
| Example 75 | Formic acid10 | | | | | | | | | |
| Example 76 | PGMEA90/ | IEX | — | Nylon | 5 | IEX | — | PTFE | 5 | IEX |
| | Formic acid10 | | | | | | | | | |
| Example 77 | PGMEA90/ | IEX | — | PP | 5 | IEX | — | PTFE | 5 | IEX |
| | Propionic acid10 | | | | | | | | | |
| Example 78 | PGMEA90/ | IEX | — | Nylon | 10 | IEX | — | PTFE | 5 | IEX |
| | Propionic acid10 | | | | | | | | | |
| Example 79 | PGMEA90/ | IEX | — | Nylon | 5 | IEX | — | PP | 5 | IEX |
| | Propionic acid10 | | | | | | | | | |
| Example 80 | PGMEA90/ | IEX | — | Nylon | 10 | IEX | — | PTFE | 5 | IEX |
| | Propionic acid10 | | | | | | | | | |
| Comparative | PGMEA90/ | PP | 200 | IEX | — | IEX | — | Nylon | 5 | UPE |
| Example 76 | Propionic acid10 | | | | | | | | | |
| Comparative | PGMEA90/ | PP | 200 | IEX | — | IEX | — | Nylon | 5 | UPE |
| Example 77 | Propionic acid10 | | | | | | | | | |
| Comparative | PGMEA90/ | PP | 200 | IEX | — | IEX | — | Nylon | 5 | UPE |
| Example 78 | Propionic acid10 | | | | | | | | | |
| Comparative | PGMEA90/ | IEX | — | Nylon | 5 | IEX | — | PTFE | 5 | IEX |
| Example 79 | Propionic acid10 | | | | | | | | | |
| Comparative | PGMEA90/ | IEX | — | Nylon | 5 | IEX | — | PTFE | 5 | IEX |
| Example 80 | Propionic acid10 | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 10 | (nm) | Material | (nm) | circulations | (counts/mm²) | defects | (/wafer) |
| Example 71 | — | UPE | 3 | 2 | 0.012 | 5 | 9 |
| Example 72 | — | UPE | 3 | 2 | 0.034 | 8 | 2 |
| Example 73 | — | UPE | 3 | 2 | 1.012 | 9 | 4 |
| Example 74 | — | UPE | 3 | 2 | 0.118 | 10 | 5 |
| Example 75 | — | UPE | 3 | 1 | 9.808 | 13 | 5 |
| Comparative | 3 | | | 3 | 2602.899 | 106 | 13 |
| Example 71 | | | | | | | |
| Comparative | 3 | | | 15 | 21.397 | 76 | 13 |
| Example 72 | | | | | | | |
| Comparative | 3 | | | 18 | 12.077 | 63 | 12 |
| Example 73 | | | | | | | |
| Comparative | — | UPE | 3 | 10 | 0.005 | 1 | 211 |
| Example 74 | | | | | | | |
| Comparative | — | UPE | 3 | 15 | 0.002 | 3 | 1264 |
| Example 75 | | | | | | | |
| Example 76 | — | UPE | 3 | 2 | 0.012 | 4 | 14 |
| Example 77 | — | UPE | 3 | 2 | 0.034 | 6 | 9 |
| Example 78 | — | UPE | 3 | 2 | 0.949 | 14 | 4 |
| Example 79 | — | UPE | 3 | 2 | 0.132 | 10 | 6 |
| Example 80 | — | UPE | 3 | 1 | 9.370 | 17 | 2 |
| Comparative | 3 | | | 3 | 1912.753 | 139 | 11 |
| Example 76 | | | | | | | |
| Comparative | 3 | | | 15 | 46.139 | 58 | 10 |
| Example 77 | | | | | | | |
| Comparative | 3 | | | 18 | 12.304 | 46 | 16 |
| Example 78 | | | | | | | |
| Comparative | — | UPE | 3 | 10 | 0.003 | 5 | 428 |
| Example 79 | | | | | | | |
| Comparative | — | UPE | 3 | 15 | 0.001 | 3 | 1451 |
| Example 80 | | | | | | | |

TABLE 11

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 11 | solvent | Material | (nm) | Material | (nm) | Material | (nm) | Material | (nm) | Material |
| Example 81 | PGMEA90/ | IEX | — | Nylon | 5 | IEX | — | PTFE | 5 | IEX |
| | Butyric acid10 | | | | | | | | | |
| Example 82 | PGMEA90/ | IEX | — | PP | 5 | IEX | — | PTFE | 5 | IEX |
| | Butyric acid10 | | | | | | | | | |
| Example 83 | PGMEA90/ | IEX | — | Nylon | 10 | IEX | — | PTFE | 5 | IEX |
| | Butyric acid10 | | | | | | | | | |
| Example 84 | PGMEA90/ | IEX | — | Nylon | 5 | IEX | — | PP | 5 | IEX |
| | Butyric acid10 | | | | | | | | | |
| Example 85 | PGMEA90/ | IEX | — | Nylon | 10 | IEX | — | PTFE | 5 | IEX |
| | Butyric acid10 | | | | | | | | | |
| Comparative | PGMEA90/ | PP | 200 | IEX | — | IEX | — | Nylon | 5 | UPE |
| Example 81 | Butyric acid10 | | | | | | | | | |
| Comparative | PGMEA90/ | PP | 200 | IEX | — | IEX | — | Nylon | 5 | UPE |
| Example 82 | Butyric acid10 | | | | | | | | | |
| Comparative | PGMEA90/ | PP | 200 | IEX | — | IEX | — | Nylon | 5 | UPE |
| Example 83 | Butyric acid10 | | | | | | | | | |
| Comparative | PGMEA90/ | IEX | — | Nylon | 5 | IEX | — | PTFE | 5 | IEX |
| Example 84 | Butyric acid10 | | | | | | | | | |
| Comparative | PGMEA90/ | IEX | — | Nylon | 5 | IEX | — | PTFE | 5 | IEX |
| Example 85 | Butyric acid10 | | | | | | | | | |
| Example 86 | PGMEA90/ | IEX | — | Nylon | 5 | IEX | — | PTFE | 5 | IEX |
| | Lactic acid10 | | | | | | | | | |
| Example 87 | PGMEA90/ | IEX | — | PP | 5 | IEX | — | PTFE | 5 | IEX |
| | Lactic acid10 | | | | | | | | | |
| Example 88 | PGMEA90/ | IEX | — | Nylon | 10 | IEX | — | PTFE | 5 | IEX |
| | Lactic acid10 | | | | | | | | | |
| Example 89 | PGMEA90/ | IEX | — | Nylon | 5 | IEX | — | PP | 5 | IEX |
| | Lactic acid10 | | | | | | | | | |
| Example 90 | PGMEA90/ | IEX | — | Nylon | 10 | IEX | — | PTFE | 5 | IEX |
| | Lactic acid10 | | | | | | | | | |
| Comparative | PGMEA90/ | PP | 200 | IEX | — | IEX | — | Nylon | 5 | UPE |
| Example 86 | Lactic acid10 | | | | | | | | | |
| Comparative | PGMEA90/ | PP | 200 | IEX | — | IEX | — | Nylon | 5 | UPE |
| Example 87 | Lactic acid10 | | | | | | | | | |
| Comparative | PGMEA90/ | PP | 200 | IEX | — | IEX | — | Nylon | 5 | UPE |
| Example 88 | Lactic acid10 | | | | | | | | | |
| Comparative | PGMEA90/ | IEX | — | Nylon | 5 | IEX | — | PTFE | 5 | IEX |
| Example 89 | Lactic acid10 | | | | | | | | | |
| Comparative | PGMEA90/ | IEX | — | Nylon | 5 | IEX | — | PTFE | 5 | IEX |
| Example 90 | Lactic acid10 | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 11 | (nm) | Material | (nm) | circulations | (counts/mm²) | defects | (/wafer) |
| Example 81 | — | UPE | 3 | 2 | 0.011 | 3 | 16 |
| Example 82 | — | UPE | 3 | 2 | 0.038 | 4 | 9 |
| Example 83 | — | UPE | 3 | 2 | 1.085 | 7 | 4 |
| Example 84 | — | UPE | 3 | 2 | 0.167 | 14 | 8 |
| Example 85 | — | UPE | 3 | 1 | 9.229 | 20 | 2 |
| Comparative | 3 | | | 3 | 1799.484 | 111 | 16 |
| Example 81 | | | | | | | |
| Comparative | 3 | | | 15 | 45.973 | 85 | 7 |
| Example 82 | | | | | | | |
| Comparative | 3 | | | 18 | 10.515 | 29 | 20 |
| Example 83 | | | | | | | |
| Comparative | — | UPE | 3 | 10 | 0.003 | 5 | 583 |
| Example 84 | | | | | | | |
| Comparative | — | UPE | 3 | 15 | 0.001 | 2 | 1399 |
| Example 85 | | | | | | | |
| Example 86 | — | UPE | 3 | 2 | 0.013 | 2 | 15 |
| Example 87 | — | UPE | 3 | 2 | 0.044 | 4 | 6 |
| Example 88 | — | UPE | 3 | 2 | 1.186 | 8 | 5 |
| Example 89 | — | UPE | 3 | 2 | 0.144 | 12 | 8 |
| Example 90 | — | UPE | 3 | 1 | 9.364 | 15 | 3 |
| Comparative | 3 | | | 3 | 2151.381 | 132 | 8 |
| Example 86 | | | | | | | |
| Comparative | 3 | | | 15 | 47.148 | 72 | 9 |
| Example 87 | | | | | | | |
| Comparative | 3 | | | 18 | 10.618 | 33 | 22 |
| Example 88 | | | | | | | |
| Comparative | — | UPE | 3 | 10 | 0.004 | 5 | 501 |
| Example 89 | | | | | | | |
| Comparative | — | UPE | 3 | 15 | 0.002 | 1 | 1634 |
| Example 90 | | | | | | | |

TABLE 12

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 12 | solvent | Material | (nm) | Material | (nm) | Material | (nm) | Material | (nm) | Material |
| Example 91 | PGMEA50/ | IEX | — | Nylon | 5 | IEX | — | PTFE | 5 | IEX |
| | Acetic acid50 | | | | | | | | | |
| Example 92 | PGMEA50/ | IEX | — | PP | 5 | IEX | — | PTFE | 5 | IEX |
| | Acetic acid50 | | | | | | | | | |
| Example 93 | PGMEA50/ | IEX | — | Nylon | 10 | IEX | — | PTFE | 5 | IEX |
| | Acetic acid50 | | | | | | | | | |
| Example 94 | PGMEA50/ | IEX | — | Nylon | 5 | IEX | — | PP | 5 | IEX |
| | Acetic acid50 | | | | | | | | | |
| Example 95 | PGMEA50/ | IEX | — | Nylon | 10 | IEX | — | PTFE | 5 | IEX |
| | Acetic acid50 | | | | | | | | | |
| Comparative | PGMEA50/ | PP | 200 | IEX | — | IEX | — | Nylon | 5 | UPE |
| Example 91 | Acetic acid50 | | | | | | | | | |
| Comparative | PGMEA50/ | PP | 200 | IEX | — | IEX | — | Nylon | 5 | UPE |
| Example 92 | Acetic acid50 | | | | | | | | | |
| Comparative | PGMEA50/ | PP | 200 | IEX | — | IEX | — | Nylon | 5 | UPE |
| Example 93 | Acetic acid50 | | | | | | | | | |
| Comparative | PGMEA50/ | IEX | — | Nylon | 5 | IEX | — | PTFE | 5 | IEX |
| Example 94 | Acetic acid50 | | | | | | | | | |
| Comparative | PGMEA50/ | IEX | — | Nylon | 5 | IEX | — | PTFE | 5 | IEX |
| Example 95 | Acetic acid50 | | | | | | | | | |
| Example 96 | PGMEA40/ | IEX | — | Nylon | 5 | IEX | — | PTFE | 5 | IEX |
| | Acetic acid60 | | | | | | | | | |
| Example 97 | PGMEA40/ | IEX | — | PP | 5 | IEX | — | PTFE | 5 | IEX |
| | Acetic acid60 | | | | | | | | | |
| Example 98 | PGMEA40/ | IEX | — | Nylon | 10 | IEX | — | PTFE | 5 | IEX |
| | Acetic acid60 | | | | | | | | | |
| Example 99 | PGMEA40/ | IEX | — | Nylon | 5 | IEX | — | PP | 5 | IEX |
| | Acetic acid60 | | | | | | | | | |
| Example 100 | PGMEA40/ | IEX | — | Nylon | 10 | IEX | — | PTFE | 5 | IEX |
| | Acetic acid60 | | | | | | | | | |
| Comparative | PGMEA40/ | PP | 200 | IEX | — | IEX | — | Nylon | 5 | UPE |
| Example 96 | Acetic acid60 | | | | | | | | | |
| Comparative | PGMEA40/ | PP | 200 | IEX | — | IEX | — | Nylon | 5 | UPE |
| Example 97 | Acetic acid60 | | | | | | | | | |
| Comparative | PGMEA40/ | PP | 200 | IEX | — | IEX | — | Nylon | 5 | UPE |
| Example 98 | Acetic acid60 | | | | | | | | | |
| Comparative | PGMEA40/ | IEX | — | Nylon | 5 | IEX | — | PTFE | 5 | IEX |
| Example 99 | Acetic acid60 | | | | | | | | | |
| Comparative | PGMEA40/ | IEX | — | Nylon | 5 | IEX | — | PTFE | 5 | IEX |
| Example 100 | Acetic acid60 | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 12 | (nm) | Material | (nm) | circulations | (counts/mm²) | defects | (/wafer) |
| Example 91 | — | UPE | 3 | 2 | 0.012 | 4 | 6 |
| Example 92 | — | UPE | 3 | 2 | 0.036 | 7 | 4 |
| Example 93 | — | UPE | 3 | 2 | 1.089 | 12 | 2 |
| Example 94 | — | UPE | 3 | 2 | 0.161 | 9 | 5 |
| Example 95 | — | UPE | 3 | 1 | 9.331 | 18 | 6 |
| Comparative | 3 | | | 3 | 1872.381 | 110 | 12 |
| Example 91 | | | | | | | |
| Comparative | 3 | | | 15 | 49.381 | 58 | 17 |
| Example 92 | | | | | | | |
| Comparative | 3 | | | 18 | 10.991 | 51 | 6 |
| Example 93 | | | | | | | |
| Comparative | — | UPE | 3 | 10 | 0.002 | 3 | 302 |
| Example 94 | | | | | | | |
| Comparative | — | UPE | 3 | 15 | 0.001 | 1 | 991 |
| Example 95 | | | | | | | |
| Example 96 | — | UPE | 3 | 2 | 0.014 | 3 | 7 |
| Example 97 | — | UPE | 3 | 2 | 0.044 | 6 | 3 |
| Example 98 | — | UPE | 3 | 2 | 1.181 | 8 | 2 |
| Example 99 | — | UPE | 3 | 2 | 0.151 | 9 | 6 |
| Example 100 | — | UPE | 3 | 1 | 9.718 | 15 | 5 |
| Comparative | 3 | | | 3 | 2231.100 | 76 | 13 |
| Example 96 | | | | | | | |
| Comparative | 3 | | | 15 | 45.139 | 56 | 11 |
| Example 97 | | | | | | | |
| Comparative | 3 | | | 18 | 10.918 | 39 | 10 |
| Example 98 | | | | | | | |
| Comparative | — | UPE | 3 | 10 | 0.003 | 6 | 206 |
| Example 99 | | | | | | | |
| Comparative | — | UPE | 3 | 15 | 0.001 | 2 | 1103 |
| Example 100 | | | | | | | |

TABLE 13

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 13 | solvent | Material | (nm) | Material | (nm) | Material | (nm) | Material | (nm) | Material |
| Example 101 | 2-Heptanone | IEX | — | Nylon | 5 | IEX | — | PTFE | 5 | IEX |
| Example 102 | 2-Heptanone | IEX | — | PP | 5 | IEX | — | PTFE | 5 | IEX |
| Example 103 | 2-Heptanone | IEX | — | Nylon | 10 | IEX | — | PTFE | 5 | IEX |
| Example 104 | 2-Heptanone | IEX | — | Nylon | 5 | IEX | — | PP | 5 | IEX |
| Example 105 | 2-Heptanone | IEX | — | Nylon | 10 | IEX | — | PTFE | 5 | IEX |
| Comparative | 2-Heptanone | PP | 200 | IEX | — | IEX | — | Nylon | 5 | UPE |
| Example 101 | | | | | | | | | | |
| Comparative | 2-Heptanone | PP | 200 | IEX | — | IEX | — | Nylon | 5 | UPE |
| Example 102 | | | | | | | | | | |
| Comparative | 2-Heptanone | PP | 200 | IEX | — | IEX | — | Nylon | 5 | UPE |
| Example 103 | | | | | | | | | | |
| Comparative | 2-Heptanone | IEX | — | Nylon | 5 | IEX | — | PTFE | 5 | IEX |
| Example 104 | | | | | | | | | | |
| Comparative | 2-Heptanone | IEX | — | Nylon | 5 | IEX | — | PTFE | 5 | IEX |
| Example 105 | | | | | | | | | | |

| | | | | | | Lithography evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 13 | (nm) | Material | (nm) | circulations | (counts/mm²) | defects | (/wafer) |
| Example 101 | — | UPE | 3 | 2 | 0.012 | 4 | 14 |
| Example 102 | — | UPE | 3 | 2 | 0.031 | 5 | 8 |
| Example 103 | — | UPE | 3 | 2 | 1.284 | 7 | 2 |
| Example 104 | — | UPE | 3 | 2 | 0.134 | 13 | 7 |
| Example 105 | — | UPE | 3 | 1 | 9.550 | 19 | 3 |
| Comparative | 3 | | | 3 | 1928.423 | 153 | 15 |
| Example 101 | | | | | | | |
| Comparative | 3 | | | 15 | 44.134 | 77 | 8 |
| Example 102 | | | | | | | |
| Comparative | 3 | | | 18 | 12.323 | 31 | 22 |
| Example 103 | | | | | | | |
| Comparative | — | UPE | 3 | 10 | 0.005 | 7 | 653 |
| Example 104 | | | | | | | |
| Comparative | — | UPE | 3 | 15 | 0.002 | 3 | 1539 |
| Example 105 | | | | | | | |

TABLE 14

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 14 | solvent | Material | (nm) | Material | (nm) | Material | (nm) | Material | (nm) | Material |
| Example 106 | IPA | IEX | — | Nylon | 5 | IEX | — | PTFE | 5 | IEX |
| Example 107 | IPA | IEX | — | PP | 5 | IEX | — | PTFE | 5 | IEX |
| Example 108 | IPA | IEX | — | Nylon | 10 | IEX | — | PTFE | 5 | IEX |
| Example 109 | IPA | IEX | — | Nylon | 5 | IEX | — | PP | 5 | IEX |
| Example 110 | IPA | IEX | — | Nylon | 10 | IEX | — | PTFE | 5 | IEX |
| Comparative | IPA | PP | 200 | IEX | — | IEX | — | Nylon | 5 | UPE |
| Example 106 | | | | | | | | | | |
| Comparative | IPA | PP | 200 | IEX | — | IEX | — | Nylon | 5 | UPE |
| Example 107 | | | | | | | | | | |
| Comparative | IPA | PP | 200 | IEX | — | IEX | — | Nylon | 5 | UPE |
| Example 108 | | | | | | | | | | |
| Comparative | IPA | IEX | — | Nylon | 5 | IEX | — | PTFE | 5 | IEX |
| Example 109 | | | | | | | | | | |
| Comparative | IPA | IEX | — | Nylon | 5 | IEX | — | PTFE | 5 | IEX |
| Example 110 | | | | | | | | | | |

| | | | | | | Wafer evaluation | |
|---|---|---|---|---|---|---|---|
| | Fifth filter | Sixth filter | | | Analysis | | Number of |
| | Pore | | Pore | | result | Number of | pattern |
| | size | | size | Number of | I value | particle | collapses |
| Table 14 | (nm) | Material | (nm) | circulations | (counts/mm²) | defects | (/wafer) |
| Example 106 | — | UPE | 3 | 2 | 0.012 | 1 | 7 |
| Example 107 | — | UPE | 3 | 2 | 0.041 | 6 | 4 |
| Example 108 | — | UPE | 3 | 2 | 1.130 | 11 | 5 |
| Example 109 | — | UPE | 3 | 2 | 0.201 | 8 | 2 |
| Example 110 | — | UPE | 3 | 1 | 9.875 | 15 | 1 |
| Comparative | 3 | | | 3 | 7133.910 | 87 | 15 |
| Example 106 | | | | | | | |
| Comparative | 3 | | | 15 | 16.198 | 57 | 15 |
| Example 107 | | | | | | | |
| Comparative | 3 | | | 18 | 11.083 | 43 | 14 |
| Example 108 | | | | | | | |
| Comparative | — | UPE | 3 | 10 | 0.005 | 2 | 301 |
| Example 109 | | | | | | | |
| Comparative | — | UPE | 3 | 15 | 0.002 | 4 | 808 |
| Example 110 | | | | | | | |

TABLE 15

| | Purification- | | | | | | | | | |
|---|---|---|---|---|---|---|---|---|---|---|
| | target | First filter | | Second filter | | Third filter | | Fourth filter | | |
| | substance | | Pore | | Pore | | Pore | | Pore | |
| | Organic | | size | | size | | size | | size | Fifth filter |
| Table 15 | solvent | Material | (nm) | Material | (nm) | Material | (nm) | Material | (nm) | Material |
| Example 111 | IPA | IEX | — | Nylon | 5 | IEX | — | PTFE | 5 | IEX |
| Example 112 | IPA | IEX | — | PF | 5 | IEX | — | PTFE | 5 | IEX |
| Example 113 | IPA | IEX | — | Nylon | 10 | IEX | — | PTFE | 5 | IEX |
| Example 114 | IPA | IEX | — | Nylon | 5 | IEX | — | PP | 5 | IEX |
| Example 115 | IPA | IEX | — | Nylon | 10 | IEX | — | PTFE | 5 | IEX |
| Comparative | IPA | PP | 200 | IEX | — | IEX | — | Nylon | 5 | UPE |
| Example 111 | | | | | | | | | | |
| Comparative | IPA | PP | 200 | IEX | — | IEX | — | Nylon | 5 | UPE |
| Example 112 | | | | | | | | | | |
| Comparative | IPA | PP | 200 | IEX | — | IEX | — | Nylon | 5 | UPE |
| Example 113 | | | | | | | | | | |
| Comparative | IPA | IEX | — | Nylon | 5 | IEX | — | PTFE | 5 | IEX |
| Example 114 | | | | | | | | | | |
| Comparative | IPA | IEX | — | Nylon | 5 | IEX | — | PTFE | 5 | IEX |
| Example 115 | | | | | | | | | | |
| Example 116 | PGMEA | IEX | — | Nylon | 5 | IEX | — | PTFE | 5 | IEX |
| Example 117 | PGMEA | IEX | — | PF | 5 | IEX | — | PTFE | 5 | IEX |
| Example 118 | PGMEA | IEX | — | Nylon | 10 | IEX | — | PTFE | 5 | IEX |
| Example 119 | PGMEA | IEX | — | Nylon | 5 | IEX | — | PP | 5 | IEX |
| Example 120 | PGMEA | IEX | — | Nylon | 10 | IEX | — | PTFE | 5 | IEX |
| Comparative | PGMEA | PP | 200 | IEX | — | IEX | — | Nylon | 5 | UPE |
| Example 116 | | | | | | | | | | |
| Comparative | PGMEA | PP | 200 | IEX | — | IEX | — | Nylon | 5 | UPE |
| Example 117 | | | | | | | | | | |
| Comparative | PGMEA | PP | 200 | IEX | — | IEX | — | Nylon | 5 | UPE |
| Example 118 | | | | | | | | | | |
| Comparative | PGMEA | IEX | — | Nylon | 5 | IEX | — | PTFE | 5 | IEX |
| Example 119 | | | | | | | | | | |
| Comparative | PGMEA | IEX | — | Nylon | 5 | IEX | — | PTFE | 5 | IEX |
| Example 120 | | | | | | | | | | |

| | Fifth filter | Sixth filter | | | Analysis | Wafer evaluation | |
|---|---|---|---|---|---|---|---|
| | Pore | | Pore | | result | Number of | Resist |
| | size | | size | Number of | I value | particle | coating |
| Table 15 | (nm) | Material | (nm) | circulations | (counts/mm²) | defects | unevenness |
| Example 111 | — | UPE | 3 | 2 | 0.012 | 9 | A |
| Example 112 | — | UPE | 3 | 2 | 0.041 | 14 | A |
| Example 113 | — | UPE | 3 | 2 | 1.130 | 18 | A |
| Example 114 | — | UPE | 3 | 2 | 0.201 | 12 | A |
| Example 115 | — | UPE | 3 | 1 | 9.875 | 22 | A |
| Comparative | 3 | | | 3 | 7133.910 | 345 | A |
| Example 111 | | | | | | | |
| Comparative | 3 | | | 15 | 16.198 | 53 | A |
| Example 112 | | | | | | | |
| Comparative | 3 | | | 18 | 11.083 | 49 | A |
| Example 113 | | | | | | | |
| Comparative | — | UPE | 3 | 10 | 0.005 | 3 | B |
| Example 114 | | | | | | | |
| Comparative | — | UPE | 3 | 15 | 0.002 | 2 | B |
| Example 115 | | | | | | | |
| Example 116 | — | UPE | 3 | 2 | 0.021 | 3 | A |
| Example 117 | — | UPE | 3 | 2 | 0.580 | 7 | A |
| Example 118 | — | UPE | 3 | 2 | 2.319 | 15 | A |
| Example 119 | — | UPE | 3 | 2 | 0.879 | 11 | A |
| Example 120 | — | UPE | 3 | 1 | 9.233 | 19 | A |
| Comparative | 3 | | | 3 | 4120.185 | 291 | A |
| Example 116 | | | | | | | |
| Comparative | 3 | | | 15 | 16.000 | 95 | A |
| Example 117 | | | | | | | |
| Comparative | 3 | | | 18 | 12.176 | 88 | A |
| Example 118 | | | | | | | |
| Comparative | — | UPE | 3 | 10 | 0.008 | 2 | B |
| Example 119 | | | | | | | |
| Comparative | — | UPE | 3 | 15 | 0.001 | 1 | B |
| Example 120 | | | | | | | |

TABLE 16

| | Purification- | | | | | | | | |
|---|---|---|---|---|---|---|---|---|---|
| | target | First filter | | Second filter | | Third filter | | Fourth filter | |
| | substance | | Pore | | Pore | | Pore | | Pore |
| | Organic | | size | | size | | size | | size |
| Table 16 | solvent | Material | (nm) | Material | (nm) | Material | (nm) | Material | (nm) |
| Example 121 | IPA | IEX | — | Nylon | 5 | IEX | — | PTFE | 5 |
| Example 122 | IPA | IEX | — | PP | 5 | IEX | — | PTFE | 5 |
| Example 123 | IPA | IEX | — | Nylon | 10 | IEX | — | PTFE | 5 |
| Example 124 | IPA | IEX | — | Nylon | 5 | IEX | — | PP | 5 |
| Example 125 | IPA | IEX | — | Nylon | 10 | IEX | — | PTFE | 5 |
| Comparative | IPA | PP | 200 | IEX | — | IEX | — | Nylon | 5 |
| Example 121 | | | | | | | | | |
| Comparative | IPA | PP | 200 | IEX | — | IEX | — | Nylon | 5 |
| Example 122 | | | | | | | | | |
| Comparative | IPA | PP | 200 | IEX | — | IEX | — | Nylon | 5 |
| Example 123 | | | | | | | | | |
| Comparative | IPA | IEX | — | Nylon | 5 | IEX | — | PTFE | 5 |
| Example 124 | | | | | | | | | |
| Comparative | IPA | IEX | — | Nylon | 5 | IEX | — | PTFE | 5 |
| Example 125 | | | | | | | | | |

| | | | | | | | Wafer |
|---|---|---|---|---|---|---|---|
| | Fifth filter | | Sixth filter | | | Analysis | evaluation |
| | | Pore | | Pore | | result | Number of |
| | | size | | size | Number of | I value | particle |
| Table 16 | Material | (nm) | Material | (nm) | circulations | (counts/mm²) | defects |
| Example 121 | IEX | — | UPE | 3 | 2 | 0.012 | 8 |
| Example 122 | IEX | — | UPE | 3 | 2 | 0.041 | 7 |
| Example 123 | IEX | — | UPE | 3 | 2 | 1.130 | 17 |
| Example 124 | IEX | — | UPE | 3 | 2 | 0.201 | 15 |
| Example 125 | IEX | — | UPE | 3 | 1 | 9.875 | 18 |
| Comparative | UPE | 3 | | | 3 | 7133.910 | 339 |
| Example 121 | | | | | | | |
| Comparative | UPE | 3 | | | 15 | 16.198 | 68 |
| Example 122 | | | | | | | |
| Comparative | UPE | 3 | | | 18 | 11.083 | 45 |
| Example 123 | | | | | | | |
| Comparative | IEX | — | UPE | 3 | 10 | 0.005 | 36 |
| Example 124 | | | | | | | |
| Comparative | IEX | — | UPE | 3 | 15 | 0.002 | 55 |
| Example 125 | | | | | | | |

### Analysis of Chemical Solutions

Methods described below were performed to analyze the chemical solutions used in Examples and Comparative Examples.

Organic Compound Content Other than Organic Solvent

A gas-chromatograph-mass spectroscopic apparatus (product name “GCMS-2020”, manufactured by SHIMADZU CORPORATION) was used to analyze the content of organic compound other than the organic solvent included in the chemical solution. The measurement conditions are as follows.
Capillary column: InertCap5MS/NP, inner diameter: 0.25 mm, length: 30 m, film thickness: 0.25 m
Sample injection method: split, constant pressure (75 kPa)
Ionization chamber temperature: 230° C.
Column oven temperature: 80° C. (2 min)−500° C. (13 min), heating rate: 15° C./min
Carrier gas: helium
Septum purge flow rate: 5 mL/min
Split ratio: 25:1
Interface temperature: 250° C.
Ion source temperature: 200° C.
Measurement mode: Scan mode, m/z=85 to 500
Sample injection amount: 1 μL

The analysis revealed that, in each of the chemical solutions, the total content of the organic compound other than the organic solvent relative to the total mass of the chemical solution was 0.1 to 1.0 mass ppm.

Metal Content Other than Fe, Ni, and Zn

The content of metal components other than Fe, Ni, and Zn (the other metal ions and the other metal-containing particles) in the chemical solutions was analyzed by ICP-MS.

The analysis apparatus employed was Agilent8900 manufactured by Agilent Technologies, Inc.

In each of the chemical solutions, the content of the other metal particles relative to the total mass of the chemical solution was 1 to 5 mass ppt.

The results in Tables 2, 3, and 14 have demonstrated that the chemical solutions of Examples 1 to 5, 6 to 10, 11 to 15, 16 to 20, and 106 to 110 in which the I values are in the predetermined range provide suppression of generation of defects, compared with the chemical solutions of Comparative Examples 1 to 5, 6 to 10, 11 to 15, 16 to 20, and 106 to 110 in which the I values are not in the predetermined range. More specifically, in the case of being used as developers and rinse solutions, the chemical solutions of Comparative Examples did not suppress particle defects or did not suppress pattern collapses while the chemical solutions of Examples suppressed both of them.

The results in Tables 4 and 15 have demonstrated that the chemical solutions of Example 21 to 25, 111 to 115, and 116 to 120 in which the I values are in the predetermined range provide suppression of generation of defects, compared with the chemical solutions of Comparative Examples 21 to 25, 111 to 115, and 116 to 120 in which the I values are not in the predetermined range. More specifically, in the case of being used as pre-wet solutions, the chemical solutions of Comparative Examples did not suppress particle defects or did not suppress resist coating unevenness while the chemical solutions of Examples suppressed both of them.

The results in Tables 5 have demonstrated that the chemical solutions of Examples 26 to 30 in which the I values are in the predetermined range provide suppression of generation of defects, compared with the chemical solutions of Comparative Examples 26 to 30 in which the I values are not in the predetermined range. More specifically, in the case of being used as resist washing solutions, the chemical solutions of Comparative Examples did not suppress particle defects or did not suppress resist scum while the chemical solutions of Examples suppressed both of them.

The results in Tables 6, 7, and 16 have demonstrated that the chemical solutions of Example 31 to 35, 36 to 40, 41 to 45, 46 to 50, and 121 to 125 in which the I values are in the predetermined range provide suppression of generation of defects, compared with the chemical solutions of Comparative Example 31 to 35, 36 to 40, 41 to 45, 46 to 50, and 121 to 125 in which the I values are not in the predetermined range. More specifically, in the case of being used as pipe washing solutions, the chemical solutions of Comparative Examples did not suppress particle defects while the chemical solutions of Examples suppressed particle defects.

The results in Tables 8 to 13 have demonstrated that the chemical solutions of Examples 51 to 105 in which the I values are in the predetermined range provide suppression of generation of defects, compared with the chemical solutions of Comparative Examples 51 to 105 in which the I values are not in the predetermined range. More specifically, in the case of being used as metal resist developers, the chemical solutions of Comparative Examples did not suppress particle defects or did not suppress pattern collapses while the chemical solutions of Examples suppressed both of them.

Note that the same purification as in Example 21 was performed except that, instead of PGMEA, an organic solvent mixture of PGMEA and propylene glycol monomethyl ether (PGME) (mass ratio of PGMEA:PGME=7:3) was used as a purification-target substance, to obtain the chemical solution. This chemical solution was evaluated as in Example 21; the I value was 0.690 and the number of particle defects was 14.

### REFERENCE SIGNS LIST

33 container section
36 analytical unit
38 carrier gas supply section
39 pipe
50 semiconductor substrate
50a surface
51 metal-containing particle
51a analytical sample
La laser beam

What is claimed is:

1. A chemical solution comprising:
an organic solvent; and
a metal-containing particle including a metal element selected from the group consisting of Fe, Ni, and Zn,
wherein an I value determined by a method X is 0.010 to 10.000,
method X: the chemical solution is applied onto a substrate to prepare a subject; a surface of the subject is analyzed by being scanned with laser using laser-ablation-inductively coupled plasma-mass spectrometry, to obtain charts for the metal elements in which an abscissa axis indicates laser scanning time and an ordinate axis indicates ion detection intensity; the ion detection intensity of the charts is accumulated for the scanning time to determine accumulated ion detection intensities of the metal elements; the accumulated ion detection intensities of the metal elements are added up to determine a total accumulated ion detection intensity; and the total accumulated ion detection intensity is divided by a laser scanning area to obtain an I value in units of counts/mm².

2. The chemical solution according to claim 1, wherein the chemical solution is one selected from the group consisting of a developer, a rinse solution, a pre-wet solution, a resist washing solution, and a pipe washing solution.

3. The chemical solution according to claim 1, wherein the organic solvent includes butyl acetate, 4-methyl-2-pentanol, cyclohexanone, propylene glycol monomethyl ether acetate, or isopropanol.

4. The chemical solution according to claim 2, wherein the organic solvent includes butyl acetate, 4-methyl-2-pentanol, cyclohexanone, propylene glycol monomethyl ether acetate, or isopropanol.

5. The chemical solution according to claim 2, wherein the chemical solution is a developer,
the organic solvent is selected from the group consisting of butyl acetate and 4-methyl-2-pentanol, or
the organic solvent is a mixture of propylene glycol monomethyl ether acetate and a liquid organic acid.

6. The chemical solution according to claim 2, wherein the chemical solution is a rinse solution, and
the organic solvent is selected from the group consisting of butyl acetate, 4-methyl-2-pentanol, and isopropanol.

7. The chemical solution according to claim 2, wherein the chemical solution is a pre-wet solution, and
the organic solvent is selected from the group consisting of cyclohexanone, propylene glycol monomethyl ether acetate, and isopropanol.

8. The chemical solution according to claim 2, wherein the chemical solution is a resist washing solution, and
the organic solvent is propylene glycol monomethyl ether acetate.

9. The chemical solution according to claim 2, wherein the chemical solution is a pipe washing solution, and
the organic solvent is selected from the group consisting of butyl acetate, 4-methyl-2-pentanol, cyclohexanone, isopropanol, and propylene glycol monomethyl ether acetate.
